(19) United States
(12) Patent Application Publication
(10) Pub. No.: US 2012/0045883 A1
(43) Pub. Date: Feb. 23, 2012

(54) METHOD FOR MANUFACTURING SOI SUBSTRATE

(75) Inventors: Yoshihiro KOMATSU, Atsugi (JP); Tomoaki MORIWAKA, Isehara (JP)

(73) Assignee: SEMICONDUCTOR ENERGY LABORATORY CO., LTD., Atsugi-shi (JP)

(21) Appl. No.: 13/210,711

(22) Filed: Aug. 16, 2011

(30) Foreign Application Priority Data
Aug. 23, 2010 (JP) 2010-186594

(51) Int. Cl. H01L 21/762

(52) U.S. Cl. 438/458; 257/E21.568

(57) ABSTRACT

An SOI substrate is manufactured by the following method. An insulating layer is formed on a semiconductor substrate; an embrittled region is formed in the semiconductor substrate on which the insulating layer is formed by irradiating the semiconductor substrate with ions; a base substrate is heated to reduce moisture content attaching to a surface of the base substrate, wherein the base substrate after the heating faces and is in contact with the semiconductor substrate in which the embrittled region is formed, so that the base substrate and the semiconductor substrate are bonded to each other; and the bonded base substrate and semiconductor substrate is heated to separate the semiconductor substrate along the embrittled region to form a semiconductor layer over the base substrate. In this manner, the SOI substrate in which bonding defects are be sufficiently reduced can be provided.

### BACKGROUND OF THE INVENTION

1. Field of the Invention

The present invention relates to a silicon-on-insulator (SOI) substrate, a manufacturing method thereof, a semiconductor device including the SOI substrate, and a manufacturing method thereof.

2. Description of the Related Art

In recent years, instead of a bulk silicon substrate, the use of a silicon-on-insulator (SOI) substrate where a thin single crystal semiconductor layer is provided over an insulating surface has been considered. Because parasitic capacitance generated by a drain of a transistor and a substrate can be reduced by use of an SOI substrate, SOI substrates are attracting attention as substrates which improve performance of semiconductor integrated circuits.

One of known methods for manufacturing SOI substrates is a Smart Cut (registered trademark) method (for example, see Patent Document 1). A summary of a method for manufacturing an SOI substrate by a Smart Cut (registered trademark) method will be described below. First, hydrogen ions are implanted into a silicon substrate by an ion implantation method for forming a microbubble layer at a predetermined depth from the surface. Next, the silicon substrate into which the hydrogen ions are implanted is bonded to another silicon substrate with a silicon oxide layer interposed therebetween. After that, heat treatment is performed so that a part of the silicon substrate into which the hydrogen ions are implanted is separated in a thin film shape at the microbubble layer. Accordingly, a silicon layer is provided over the other bonded silicon substrate.

A method for forming a silicon layer over a base substrate using glass by using such a Smart Cut (registered trademark) method has been proposed (for example, see Patent Document 2). Glass substrates can have a larger area and are less expensive than silicon substrates; thus, glass substrates are mainly used in manufacturing liquid crystal display devices or the like. By using a glass substrate as a base substrate, a large-sized inexpensive SOI substrate can be manufactured.

### REFERENCE

[Patent Document 1] Japanese Published Patent Application No. H05-211128
[Patent Document 2]: Japanese Published Patent Application No. 2005-252244

### SUMMARY OF THE INVENTION

Meanwhile, when a silicon layer is formed over a base substrate with the use of the above Smart Cut (registered trademark) method, or the like, defects due to the bonding at the bonding interface (bonding defects) may be caused. In a portion where such a bonding defect is present, a silicon layer cannot be formed in some cases. In this case, an area which can be used as an SOI substrate is reduced, a problem of decrease in the number of semiconductor devices that can be manufactured using this is caused, for example. Further, even if a silicon layer can be formed in a portion where bonding defects are present, when a semiconductor device is formed in the portion, a problem of deterioration in characteristics of a semiconductor device is caused.

In view of the foregoing, an object of the present invention is to provide an SOI substrate in which bonding defects are sufficiently reduced. It is another object to provide a semiconductor device using such an SOI substrate.

One embodiment of the disclosed present invention is a method for manufacturing an SOI substrate, in which an insulating layer is formed on a semiconductor substrate; an embrittled region is formed in the semiconductor substrate on which the insulating layer is formed by irradiating the semiconductor substrate with ions; a base substrate is heated to reduce moisture content attaching to a surface of the base substrate, wherein the base substrate after the heating faces and is in contact with the semiconductor substrate in which the embrittled region is formed, so that the base substrate and the semiconductor substrate are bonded to each other; and the bonded base substrate and semiconductor substrate is heated to separate the semiconductor substrate along the embrittled region to form a semiconductor layer over the base substrate.

Further, one embodiment of the disclosed present invention is a method for manufacturing an SOI substrate, in which an insulating layer is formed on a semiconductor substrate; an embrittled region is formed in the semiconductor substrate on which the insulating layer is formed by irradiating the semiconductor substrate with ions; a base substrate is heated and then cooled to reduce moisture content attaching to a surface of the base substrate, wherein the base substrate after the cooling faces and is in contact with the semiconductor substrate in which the embrittled region is formed, so that the base substrate and the semiconductor substrate are bonded to each other; and the bonded base substrate and semiconductor substrate is heated to separate the semiconductor substrate along the embrittled region to form a semiconductor layer over the base substrate.

Further, one embodiment of the disclosed present invention is a method for manufacturing an SOI substrate, in which an insulating layer is formed on each of a plurality of semiconductor substrates; an embrittled region is formed in each of the plurality of semiconductor substrates on which the insulating layers are formed by irradiating the semiconductor substrate with ions; a base substrate is heated to reduce moisture content attaching to a surface of the base substrate, wherein the base substrate after the heating faces and is in contact with the plurality of semiconductor substrates in which the embrittled regions are formed, so that the base substrate and the plurality of semiconductor substrates are bonded to each other; and the bonded base substrate and plurality of semiconductor substrates are heated to separate the plurality of semiconductor substrates along the embrittled regions to form a plurality of semiconductor layers over the base substrate.

Further, in the above method, the semiconductor layer is formed over the base substrate, and then the semiconductor layer can be irradiated with laser light. Further, in the above method, the base substrate can be heated to higher than or equal to 55° C. and lower than or equal to 95° C. in the step of heating the base substrate. Further, in the above method, the base substrate can be heated by spraying a gas whose temperature is higher than or equal to a heating temperature of the base substrate in the step of heating the base substrate. Further, in the above method, the base substrate can be cooled to higher than or equal to room temperature and lower than or equal to 95° C. in the step of heating and then cooling of the base substrate. Further, in the above method, the base substrate can be a glass substrate. Further, in the above method, ozone or oxygen in an active state can be combined with ultraviolet light to perform surface treatment on the base substrate and the semiconductor substrate before the base substrate and the semiconductor substrate are bonded to each other.

In general, the term “SOI substrate” means a semiconductor substrate in which a silicon semiconductor layer is provided over an insulating surface. In this specification and the like, the term “SOI substrate” also includes a semiconductor substrate in which a semiconductor layer formed using a material other than silicon is provided over an insulating surface in its category. That is, a semiconductor layer included in the “SOI substrate” is not limited to a silicon layer. In addition, in this specification and the like, a semiconductor substrate means not only a substrate formed using only a semiconductor material but also all substrates including a semiconductor material. Namely, in this specification and the like, the “SOI substrate” is also included in the category of a semiconductor substrate.

Note that in this specification and the like, the term “single crystal” means a crystal in which, when a certain crystal axis is focused, the direction of the crystal axis is oriented in a similar direction in any portion of a sample. That is, the single crystal includes a crystal in which the direction of crystal axes is uniform as described above even when it includes a crystal defect or a dangling bond.

Further, in this specification and the like, the term “semiconductor device” means all devices which can operate by utilizing semiconductor characteristics. For example, a display device and an integrated circuit are included in the category of the semiconductor device. Furthermore, in this specification and the like, the display device includes a light emitting display device, a liquid crystal display device, and a display device including an electrophoretic element. A light emitting display device includes a light emitting element, and a liquid crystal display device includes a liquid crystal element. A light emitting element includes, in its scope, an element whose luminance is controlled by a current or a voltage, and specifically includes an inorganic electroluminescent (EL) element, an organic EL element, and the like.

According to one embodiment of the disclosed invention, an SOI substrate in which bonding defects are sufficiently reduced can be provided. Further, with the use of such an SOI substrate, characteristics of a semiconductor can be improved.

### BRIEF DESCRIPTION OF THE DRAWINGS

FIGS. 1A, 1B-1 to 1B-3, 1C, 1D, and 1E are cross-sectional views illustrating an example of a method for manufacturing an SOI substrate.

FIGS. 2A to 2D illustrate an example of a method for bonding a base substrate and a semiconductor substrate.

FIGS. 3A to 3D illustrate an example of a method for bonding a base substrate and a semiconductor substrate.

FIGS. 4A-1 and 4A-2, 4B-1 to 4B-3, 4C, 4D, and 4E are cross-sectional views illustrating an example of a method for manufacturing an SOI substrate.

FIG. 5 is a perspective view illustrating an example of an SOI substrate.

FIGS. 6A to 6C illustrate an example of a method for bonding a base substrate and a semiconductor substrate.

FIGS. 7A to 7D are cross-sectional views illustrating a method for manufacturing a semiconductor device.

FIGS. 8A to 8D are cross-sectional views illustrating a method for manufacturing a semiconductor device.

FIGS. 9A and 9B are a cross-sectional view and a plan view illustrating a method for manufacturing a semiconductor device, respectively.

FIGS. 10A to 10F each illustrate an electronic device.

FIG. 11 shows the number of bonding defects and heating conditions of an SOI substrate.

FIG. 12 shows the number of voids and heating conditions of an SOI substrate.

FIGS. 13A and 13B show TDS intensity and substrate temperature.

### DETAILED DESCRIPTION OF THE INVENTION

Hereinafter, Embodiments are described in detail using the drawings. Note that the present invention is not limited to the description of the embodiments, and it is apparent to those skilled in the art that embodiments and details can be modified in various ways without departing from the spirit of the present invention disclosed in this specification and the like. A structure of the different embodiment can be implemented by combination appropriately. Note that in the structures of the present invention described below, common reference numerals are used for portions that are the same or have similar functions, and repeated description will be omitted.

### Embodiment 1

In this embodiment, examples for a method of manufacturing an SOI substrate will be described with reference to drawings.

### <First Mode>

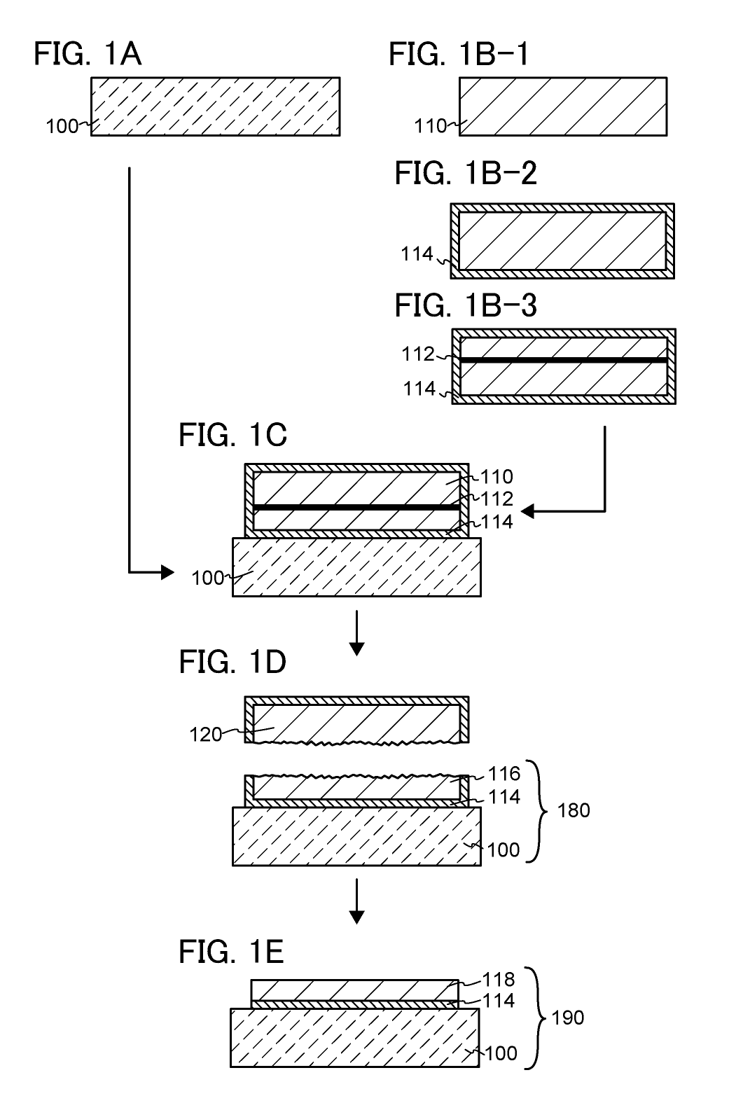

First, a manufacturing method according to First Mode will be described with reference to FIGS. 1A to 1E, FIGS. 2A to 2D, and FIGS. 3A to 3D.

First, a base substrate 100 is prepared (see FIG. 1A). As the base substrate 100, a light-transmitting glass substrate used for a liquid crystal display device or the like can be used. As the glass substrate, the one whose stain point is 600° C. or more is preferably used. Further, it is preferable that the glass substrate be a non-alkali glass substrate. As a material of the non-alkali glass substrate, a glass material such as aluminosilicate glass, aluminoborosilicate glass, or barium borosilicate glass can be used, for example. When a glass substrate is used as the base substrate 100, the base substrate 100 can have a large area and cost can be reduced as compared to the case of using a silicon substrate.

Further, as the base substrate 100, a substrate which is formed of an insulator, such as an insulating ceramic substrate, a quartz substrate, or a sapphire substrate; a substrate which is formed of a semiconductor such as semiconductor ceramic or silicon; a substrate which is formed of a conductor such as metal or stainless steel; or the like can be used. Furthermore, as the base substrate 100, a plastic substrate having heat resistance which can withstand process temperature in a manufacturing process may also be used. The case where a glass substrate processed to have a rectangular shape is used as the base substrate 100 will be described below. Note that unless otherwise specified, a square is also included as a rectangle.

Next, a semiconductor substrate 110 is prepared as a bonding substrate (see FIG. 1B-1). As the semiconductor substrate 110, a polycrystalline semiconductor substrate or a single crystal semiconductor substrate can be used. As the polycrystalline semiconductor substrate or the single crystal semiconductor substrate, for example, a semiconductor substrate that is formed of an element which belongs to Group 14, such as a polycrystalline or single crystal silicon substrate, a polycrystalline or single germanium substrate, a polycrystalline or single silicon germanium substrate, or a polycrystalline or single silicon carbide substrate or a polycrystalline or single compound semiconductor substrate using gallium arsenide, indium phosphide, or the like can be given. Typical silicon substrates are circular silicon substrates which are 5 inches (125 mm) in diameter, 6 inches (150 mm) in diameter, 8 inches (200 mm) in diameter, and 12 inches (300 mm) in diameter. Note that the shape of a silicon substrate is not limited to the circular shape, and a silicon substrate processed to have a rectangular shape or the like can also be used. The case where a silicon substrate processed to have a rectangular shape is used as the semiconductor substrate 110 will be described below.

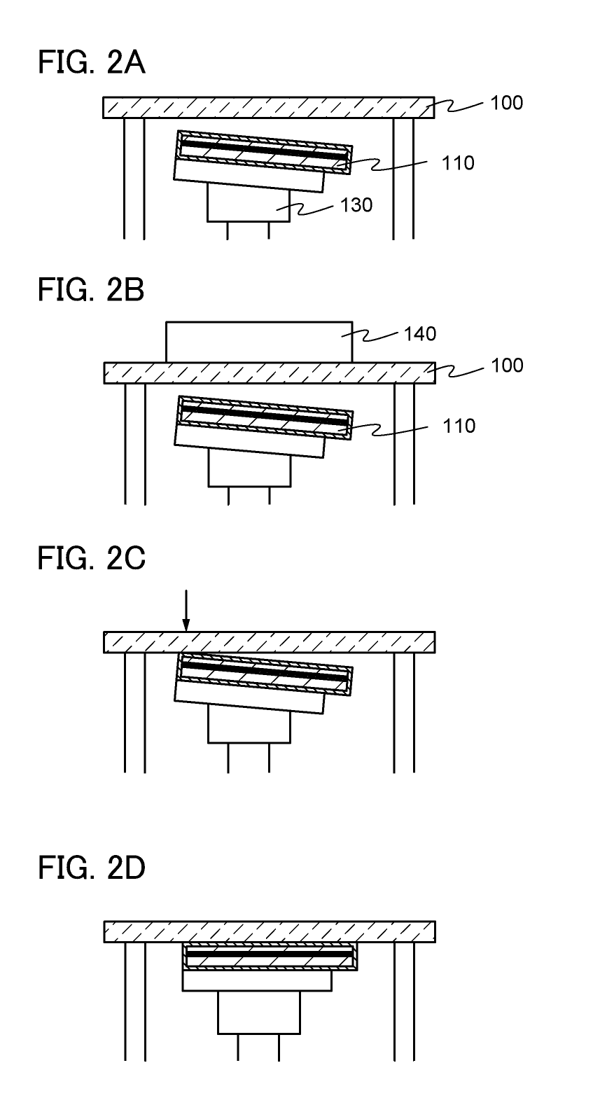

Next, an insulating layer 114 is formed on the semiconductor substrate 110 (see FIG. 1B-2).

As the insulating layer 114, a single layer of a silicon oxide layer, a silicon oxynitride layer, a silicon nitride layer, a silicon nitride oxide layer, or the like or a stack of these layers can be used. These layers can be formed by a CVD method, a sputtering method, or the like. When a CVD method is employed to form the insulating layer 114, the use of a silicon oxide layer formed using organosilane, such as tetraethoxysilane (abbreviation: TEOS) (chemical formula: Si(OC₂H₅)₄), as the insulating layer 114 is preferable in terms of productivity.

Note that a silicon oxynitride layer refers to a layer that contains more oxygen than nitrogen and, in the case where measurements are performed using Rutherford backscattering spectrometry (RBS) and hydrogen forward scattering (HFS), includes oxygen, nitrogen, silicon, and hydrogen at concentrations ranging from 50 atomic % to 70 atomic %, 0.5 atomic % to 15 atomic %, 25 atomic % to 35 atomic %, and 0.1 atomic % to 10 atomic %, respectively. Note that a silicon nitride oxide layer refers to a layer that contains more nitrogen than oxygen and, in the case where measurements are performed using RBS and HFS, includes oxygen, nitrogen, silicon, and hydrogen at concentrations ranging from 5 atomic % to 30 atomic %, 20 atomic % to 50 atomic %, 25 atomic % to 35 atomic %, and 15 atomic % to 25 atomic %, respectively. Note that percentages of nitrogen, oxygen, silicon, and hydrogen fall within the ranges given above, where the total number of atoms contained in the silicon oxynitride or the silicon nitride oxide is defined as 100 atomic %.

Alternatively, the insulating layer 114 may be formed by performing thermal oxidation treatment on the semiconductor substrate 110. In this case, the thermal oxidation treatment is preferably performed in an oxidation atmosphere to which halogen is added. As an example of such thermal oxidation treatment, it is preferable that thermal oxidation treatment be performed in an atmosphere containing hydrogen chloride (HCl) at 0.5 volume % to 10 volume % (preferably, 3 volume %) with respect to oxygen and at a temperature of 900° C. to 1150° C. (for example, 950° C.). Processing time is set at 0.1 hours to 6 hours, preferably 0.5 hours to 1 hour. The thickness of an oxide layer to be formed is 10 nm to 1000 nm (preferably, 50 nm to 200 nm), for example, 100 nm.

In this embodiment, by subjecting the semiconductor substrate 110 to thermal oxidation treatment in an atmosphere containing hydrogen chloride (HCl), the insulating layer 114 (here, a silicon oxide layer) is formed. Accordingly, the insulating layer 114 includes chlorine atoms.

Note that a structure in which the insulating layer 114 is not provided may be employed as long as a problem does not particularly occur in bonding.

Next, the semiconductor substrate 110 on which the insulating layer 114 is formed is irradiated with ions, so that an embrittled region 112 is formed in the semiconductor substrate 110 (see FIG. 1B-3). For example, irradiation with an ion beam including ions accelerated by an electric field is performed, so that the embrittled region 112 is formed at a predetermined depth from the surface of the semiconductor substrate 110. Accelerating energy of the ion beam or the incidence angle thereof controls the depth at which the embrittled region 112 is formed. In other words, the embrittled region 112 is formed in a region at a depth the same or substantially the same as the average penetration depth of the ions. Here, the depth at which the embrittled region 112 is formed is preferably uniform in the entire area of the semiconductor substrate 110.

Further, the depth at which the above-described embrittled region 112 is formed determines the thickness of the semiconductor layer which is to be separated from the semiconductor substrate 110. The depth at which the embrittled region 112 is formed is greater than or equal to 50 nm and less than or equal to 1 μm, preferably greater than or equal to 50 nm and less than or equal to 300 nm from the surface of the semiconductor substrate 110.

An ion implantation apparatus or an ion doping apparatus can be used in order to add ions to the semiconductor substrate 110. In an ion implantation apparatus, a source gas is excited to generate ion species, the generated ion species are mass-separated, and an object to be processed is irradiated with the ion species having a predetermined mass. In an ion doping apparatus, a process gas is excited to generate ion species, the generated ion species are not mass-separated, and an object to be processed is irradiated with the generated ion species. Note that in the ion doping apparatus provided with a mass separator, ion irradiation with mass separation can also be performed as in the ion implantation apparatus.

In the case of using an ion doping apparatus, a process for forming the embrittled region 112 can be performed, for example, under the following conditions:

Accelerating voltage: greater than or equal to 10 kV and less than or equal to 100 kV (preferably greater than or equal to 30 kV and less than or equal to 80 kV)

Dose: greater than or equal to 1×10¹⁶ ions/cm² and less than or equal to 4×10¹⁶ ions/cm²

Beam current intensity: greater than or equal to 2 μA/cm² (preferably greater than or equal to 5 μA/cm², more preferably greater than or equal to 10 μA/cm²)

When an ion doping apparatus is used, a gas containing hydrogen can be used as the source gas. By using a gas containing hydrogen, H⁺, H₂⁺, and H₃⁺ can be generated as ion species. When a hydrogen gas is used as the source gas, it is preferable to perform irradiation with a large amount of H₃⁺ ions. Specifically, in an ion beam, the proportion of H₃⁺ ions in the total of H⁺, H₂⁺, and H₃⁺ ions is preferably 70% or more. More preferably, the proportion of H₃⁺ ions is 80% or more. By increasing the proportion of H₃⁺ ions in this manner, the embrittled region 112 can contain hydrogen at a concentration of 1×10²⁰ atoms/cm³ or higher. This facilitates a split at the embrittled region 112. Furthermore, by irradiation with a large number of H₃⁺ ions, the embrittled region 112 can be formed in a shorter period of time as compared with the case of irradiation with H⁺ ions and H₂⁺ ions. Moreover, the use of H₃⁺ ions can reduce the average penetration depth of ions; thus, the embrittled region 112 can be formed in a shallow region.

When an ion implantation apparatus is used, preferably, irradiation with H₃⁺ ions is performed by mass separation. It is needless to say that irradiation with H⁺ or H₂⁺ ions may be performed. Note that, since ion species are selected to perform irradiation in the case of using an ion implantation apparatus, ion irradiation efficiency is decreased compared to the case of using an ion doping apparatus, in some cases.

As a source gas for the ion irradiation step, as well as a gas containing hydrogen, one or more kinds of gases selected from a rare gas such as helium or argon; a halogen gas typified by a fluorine gas or a chlorine gas; or a halogen compound gas such as a fluorine compound gas (e.g., BF₃) can be used. When helium is used for a source gas, an ion beam with high proportion of He⁺ ions can be formed without mass separation. By using such ion beams, the embrittled region 112 can be formed efficiently.

Further, the embrittled region 112 can be formed through ion irradiation divided into plural steps. In this case, a different source gas may be used in each ion irradiation, or the same source gas may be used. For example, ion irradiation can be performed using a gas containing hydrogen as a source gas after ion irradiation is performed using a rare gas as a source gas. Also, ion irradiation is performed first using a halogen gas or a halogen compound gas, and then ion irradiation can be performed using a gas containing hydrogen.

Next, at least one of the insulating layer 114 formed over the semiconductor substrate 110 and the base substrate 100 is preferably subjected to surface treatment. Surface treatment can improve the bonding strength at the bonding interface between the semiconductor substrate 110 and the base substrate 100. Moreover, surface treatment can reduce particles (also referred to as dust) or the like on the surface of the substrate, so that bonding defects due to the particles or the like can be suppressed.

As examples of the surface treatment, wet treatment, dry treatment, and combination of wet treatment and dry treatment can be given. Alternatively, a combination of different wet treatments or a combination of different dry treatments may be employed.

As examples of the wet treatment, ozone treatment using ozone water (ozone water cleaning), megasonic cleaning, two-fluid cleaning (method in which functional water such as pure water or hydrogenated water and a carrier gas such as nitrogen are sprayed together), and the like can be given. As examples of the dry treatment, ultraviolet treatment, ozone treatment, plasma treatment, plasma treatment with bias application, radical treatment, and the like can be given. The surface treatment described above can enhance hydrophilicity and cleanliness of a surface of the object to be processed (the semiconductor substrate 110, the insulating layer 114 formed on the semiconductor substrate 110, and the base substrate 100). As the result, the bonding strength at the bonding interface can be improved. Moreover, surface treatment can reduce particles or the like on the surface of the substrate, so that bonding defects due to the particles or the like can be suppressed.

The wet treatment is effective for the removal of macro dust and the like adhering to a surface of the object to be processed. The dry treatment is effective for the removal or decomposition of micro dust such as an organic substance adhering to a surface of the object to be processed. Therefore, the case in which the dry treatment such as ultraviolet treatment is performed on the object to be processed and then the wet treatment such as cleaning is performed on the object is preferable because the surface of the object can be made clean and hydrophilic and generation of watermarks on the surface of the object can be suppressed.

After the wet treatment, the object to be processed is preferably dried. As the drying method, a method of spraying a gas (also referred to as an air knife), drying with IPA (a method in which water is replaced with the vapor of isopropyl alcohol), drying with spinning, or the like can be used.

As an example of the dry treatment, plasma treatment will be described. Here, the plasma treatment is performed in a plasma state which is produced by introducing an inert gas (such as an argon gas) into a chamber in a vacuum state and applying a bias voltage to a surface of the object to be processed (e.g., the base substrate 100). Electrons and argon cations are present in plasma and the argon cations are accelerated in a cathode direction (to the base substrate 100 side). By collision of the accelerated argon cations with the surface of the base substrate 100, the surface of the base substrate 100 is etched by sputtering. At this time, a projection of the surface of the base substrate 100 is preferentially etched by sputtering; thus, the planarity of the surface of the base substrate 100 can be improved. Further, by the accelerated argon cations, impurities such as organic substances on the base substrate 100 can be removed and the base substrate can be activated. Alternatively, plasma treatment can be performed by introducing a reactive gas (such as an oxygen gas or a nitrogen gas) in addition to the inert gas into a chamber in a vacuum state and applying a bias voltage to a surface to be treated to create a plasma state. When the reactive gas is introduced, it is possible to repair defects caused by etching of the surface of the base substrate 100 with sputtering. The plasma treatment causes generation of a dangling bond on a surface of the object to be processed, so that the surface is activated and becomes a state that is suitable for bonding. Further, ions accelerated by the plasma treatment are implanted into a surface layer of the object to be processed, whereby a defect such as distortion is formed in the surface layer. Accordingly, moisture at the bonding interface is easily diffused, whereby absorption of the moisture can be increased.

As another example of the dry treatment, the surface treatment using oxygen in an active state in combination with ultraviolet light will be described.

Ozone or oxygen in an active state such as singlet oxygen enables organic substances adhering to the surface of the object to be processed to be removed or decomposed effectively. Further, the treatment using ozone or oxygen in an active state such as singlet oxygen may be combined with treatment using ultraviolet light having a wavelength less than 200 nm, so that the organic substances adhering to the surface of the object to be processed can be removed more effectively.

For example, irradiation with ultraviolet light in an atmosphere containing oxygen is performed to perform the surface treatment of the object to be processed. Irradiation with ultraviolet light having a wavelength less than 200 nm and ultraviolet light having a wavelength greater than or equal to 200 nm in an atmosphere containing oxygen may be performed, so that ozone and singlet oxygen can be generated. Alternatively, irradiation with ultraviolet light having a wavelength less than 180 nm may be performed, so that ozone and singlet oxygen can be generated.

Examples of reactions which occur by performing irradiation with ultraviolet light having a wavelength less than 200 nm and ultraviolet light having a wavelength greater than or equal to 200 nm in an atmosphere containing oxygen are described.

O₂+hν(λ₁ nm)→O(³P)+O(³P) (1)

O(³P)+O₂→O₃ (2)

O₃+hν(λ₂ nm)→O(¹D)+O₂ (3)

In the above reaction formula (1), irradiation with light (hν) having a wavelength (λ₁ nm) less than 200 nm in an atmosphere containing oxygen (O₂) is performed to generate an oxygen atom (O(³P)) in a ground state. Next, in the reaction formula (2), an oxygen atom (O(³P)) in a ground state and oxygen (O₂) are reacted with each other to generate ozone (O₃). Then, in the reaction formula (3), irradiation with light having a wavelength (λ₂ nm) greater than or equal to 200 nm in an atmosphere containing generated ozone (O₃) is performed to generate singlet oxygen O(¹D) in an excited state. In an atmosphere containing oxygen, irradiation with ultraviolet light having a wavelength less than 200 nm is performed to generate ozone while irradiation with ultraviolet light having a wavelength greater than or equal to 200 nm is performed to generate singlet oxygen by decomposing ozone. The surface treatment as described above can be performed by, for example, irradiation with a low-pressure mercury lamp (λ₁=185 nm, λ₂=254 nm) in an atmosphere containing oxygen.

Further, examples of reactions which occur by performing irradiation with ultraviolet light having a wavelength less than 180 nm in an atmosphere containing oxygen are described.

O₂+hν(λ₃ nm)→O(¹D)+O(³P) (4)

O(³P)+O₂→O₃ (5)

O₃+hν(λ₃ nm)→O(¹D)+O₂ (6)

In the above reaction formula (4), irradiation with light having a wavelength (λ₃ nm) less than 180 nm in an atmosphere containing oxygen (O₂) is performed to generate singlet oxygen O(¹D) in an excited state and an oxygen atom (O(³P)) in a ground state. Next, in the reaction formula (5), an oxygen atom (O(³P)) in a ground state and oxygen (O₂) are reacted with each other to generate ozone (O₃). In the reaction formula (6), irradiation with light having a wavelength (λ₃ nm) less than 180 nm in an atmosphere containing generated ozone (O₃) is performed to generate singlet oxygen in an excited state and oxygen. In an atmosphere containing oxygen, irradiation with ultraviolet light having a wavelength less than 180 nm is performed to generate ozone and to generate singlet oxygen by decomposing ozone or oxygen. The surface treatment as described above can be performed by, for example, irradiation with a Xe excimer UV lamp in an atmosphere containing oxygen.

As described above, the light having a wavelength less than 200 nm causes breakage of a chemical bond in an organic substance and the like adhering to the surface of the object to be processed. With ozone or singlet oxygen, an organic substance adhering to the surface of the object, the organic substance in which the chemical bond is broken, or the like can be removed by oxidative decomposition. Therefore, the surface treatment described above can enhance hydrophilicity and cleanliness of a surface of the object to be processed; thus, bonding defects can be suppressed when the semiconductor substrate 110 and the base substrate 100 are bonded to each other.

In this embodiment, as the surface treatment, the dry treatment and the wet treatment are performed in combination on the base substrate 100 and the semiconductor substrate 110. First, as the dry treatment, irradiation using a Xe excimer UV lamp is performed in an atmosphere containing oxygen. Next, as the wet treatment, cleaning with an alkaline cleaner, brush cleaning, and two-fluid cleaning (a method in which pure water and air are sprayed together) are performed. After that, with the use of a method of spraying a gas (an air knife) or drying with IPA, the base substrate 100 and the semiconductor substrate 110 are dried.

Next, the base substrate 100 and the semiconductor substrate 110 are bonded to each other. Specifically, the base substrate 100 faces the semiconductor substrate 110, and the base substrate 100 and the insulating layer 114 formed on the semiconductor substrate 110 are bonded to each other. A method for bonding the base substrate 100 and the semiconductor substrate 110 will be described with reference to FIGS. 2A to 2D.

In this embodiment, the base substrate 100 is provided over and close to the semiconductor substrate 110 mounted on a jig 130 at a small interval (about several millimeters) (see FIG. 2A). At this time, the base substrate 100 and a surface of the semiconductor substrate 110 in which the embrittled region is formed are provided to face each other. Further, with the use of the jig 130, the semiconductor substrate 110 is provided to be slightly inclined to the base substrate 100 (at about an angle of several degrees). The base substrate 100 is provided to be close and be inclined to the semiconductor substrate 110, whereby a first contact point which is a starting point of bonding of the base substrate 100 and the semiconductor substrate 110 can be set as appropriate, and the base substrate 100 and the semiconductor substrate 110 can be stably bonded to each other. Note that there is no particular limitation on the interval and the angle between the base substrate 100 and the semiconductor substrate 110, which are set as appropriate depending on the bonding.

Next, a hot plate 140 is provided over the base substrate 100 and the base substrate 100 is heated by heating the hot plate 140 (see FIG. 2B). The heating temperature of the base substrate 100 is higher than or equal to 50° C. and lower than or equal to 100° C., preferably, higher than or equal to 55° C. and lower than or equal to 95° C. There is no particular limitation on the heating time, which is set as appropriate so that the base substrate 100 reaches a desired temperature. For example, the base substrate 100 can be heated for 180 seconds.

Note that the case where the base substrate 100 is heated is described in this embodiment; however, one embodiment of the present invention is not limited to this. The semiconductor substrate 110 may be heated, or both of the base substrate 100 and the semiconductor substrate 110 may be heated. When the semiconductor substrate 110 is heated, the semiconductor substrate 110 may be heated with the use of the hot plate as in the case where the base substrate is heated. Alternatively, the semiconductor substrate 110 may be heated by provision of a heating unit in the jig 130.

Further, the base substrate is heated in this embodiment with the use of the hot plate 140; however, one embodiment of the present invention is not limited to this. For example, the base substrate may be heated by irradiation with lamp light of a halogen lamp. Alternatively, in a drying step after the wet treatment, the base substrate may be heated by spraying a gas whose temperature is higher than or equal to a heating temperature of the base substrate (such a method is also referred to as an air knife). When the base substrate is heated by spraying a gas whose temperature is higher than or equal to a heating temperature of the base substrate, the substrate can be heated at the same time as the drying step after the wet treatment. Accordingly, this is preferable because the process can be simplified. The temperature of a gas to be sprayed and the time for spraying the gas are set as appropriate so that the temperature of the base substrate is higher than or equal to 50° C. and lower than or equal to 100° C., preferably, higher than or equal to 55° C. and lower than or equal to 95° C.

Next, the base substrate 100 heated to a desired temperature is pressed, whereby an end portion of the base substrate 100 is in contact with an end portion of the semiconductor substrate 110 (see FIG. 2C). Alternatively, with the use of a pin or the like, a point of the base substrate 100 or the semiconductor substrate 110, for example, a central portion of the base substrate 100 is pressed, whereby the base substrate 100 may be in contact with the semiconductor substrate 110. The base substrate 100 and the semiconductor substrate 110 start to be bonded to each other from a portion where they are in contact with each other, and the bonding progresses to form a concentric circle from the start point. For example, when the bonding starts from one of the corner portions of the base substrate 100 and the semiconductor substrate 110, the bonding progresses to form a concentric circle toward the opposite corner of the corner portion, which forms a bonding over the entire surface (see FIG. 1C and FIG. 2D).

When the base substrate 100 and the semiconductor substrate 110 are bonded to each other, bonding defects may be caused at the bonding interface depending on the moisture content on the base substrate 100 and the semiconductor substrate 110, and the speed of the bonding.

A hydrogen bond or van der Waals forces act on the bonding of the base substrate 100 and the semiconductor substrate 110. In order to make a hydrogen bond or van der Waals forces act, a hydroxyl group and water are needed. Therefore, when a hydroxyl group and water on the base substrate 100 and the semiconductor substrate 110 are insufficient, the base substrate 100 and the semiconductor substrate 110 are not voluntarily bonded to each other and the bonding cannot be performed.

However, when the moisture on the base substrate 100 and the semiconductor substrate 110 is excessive, the bonding progresses rapidly and a gas or particles are confined at the bonding interface. Further, in the outer edge portion of the semiconductor substrate 110 or near the point where the bonding is finished, speed of the bonding varies easily and a gas or particles tend to be confined easily. When a gas or particles are confined, a minute space is generated between the base substrate 100 and the semiconductor substrate 110; thus, bonding defects are caused when the base substrate 100 and the semiconductor substrate 110 are separated in a later step. In this specification or the like, a bonding defect caused by confinement of such a gas or particles is referred to as a void. Note that the outer edge portion of the semiconductor substrate 110 means a region within approximately 5 mm from an edge of the semiconductor substrate 110.

Further, when the moisture on the base substrate 100 and the semiconductor substrate 110 is excessive, unnecessary moisture for the bonding (hereinafter referred to as surplus moisture) on the surfaces of both the substrates remains at the bonding interface of the base substrate 100 and the semiconductor substrate 110. When surplus moisture remains at the bonding interface, the surplus moisture is heated and is evaporated in the subsequent heat treatment step, laser light irradiation step, or the like. Accordingly, a void is formed in a portion where surplus moisture is present or the void bursts, whereby bonding defects such as bumps of a silicon layer or lacks of the silicon layer or a silicon oxide film become apparent. Bonding defects caused by such surplus moisture are distributed over the entire substrate and is a big cause of the bonding defects.

Accordingly, at least one of the base substrate 100 and the semiconductor substrate 110 is heated, whereby surplus moisture can be reduced while necessary moisture content for the bonding remains on the base substrate 100 and the semiconductor substrate 110. Thus, confinement of a gas or particles at the bonding interface can be suppressed. Therefore, voids generated at the bonding interface (especially, at a distance of approximately 5 mm from an edge of the substrate) can be reduced. Consequently, residual surplus moisture at the bonding interface can be suppressed. Accordingly, bonding defects caused by surplus moisture can be reduced in a later step.

Furthermore, when plasma treatment is performed as the surface treatment, accelerated ions are introduced into the surface layers of the base substrate 100 and the semiconductor substrate 110, whereby a defect such as a distortion is formed in the surface layers. Accordingly, diffusion of surplus moisture at the bonding interface becomes easy and the surplus moisture can be absorbed in a defect such as a distortion of the surface layers. Thus, the residual surplus moisture at the bonding interface can be suppressed. Accordingly, bonding defects caused by surplus moisture can be reduced in a later step.

As for the heating temperature of the base substrate 100, the moisture content on the base substrate 100 and the semiconductor substrate 110 becomes optimal at the time when the bonding temperature of the base substrate 100 is higher than or equal to 50° C. and lower than or equal to 100° C., preferably higher than or equal to 55° C. and lower than or equal to 95° C. It was found by trial and error of the present inventors. From the experimental result, it was found that when the heating temperature is lower than 50° C., an effect of reducing bonding defects can not be sufficiently obtained because of excessive moisture and when the heating temperature is higher than or equal to 100° C., moisture attaching to the surface of the substrate is insufficient and the spontaneous bonding does not occur.

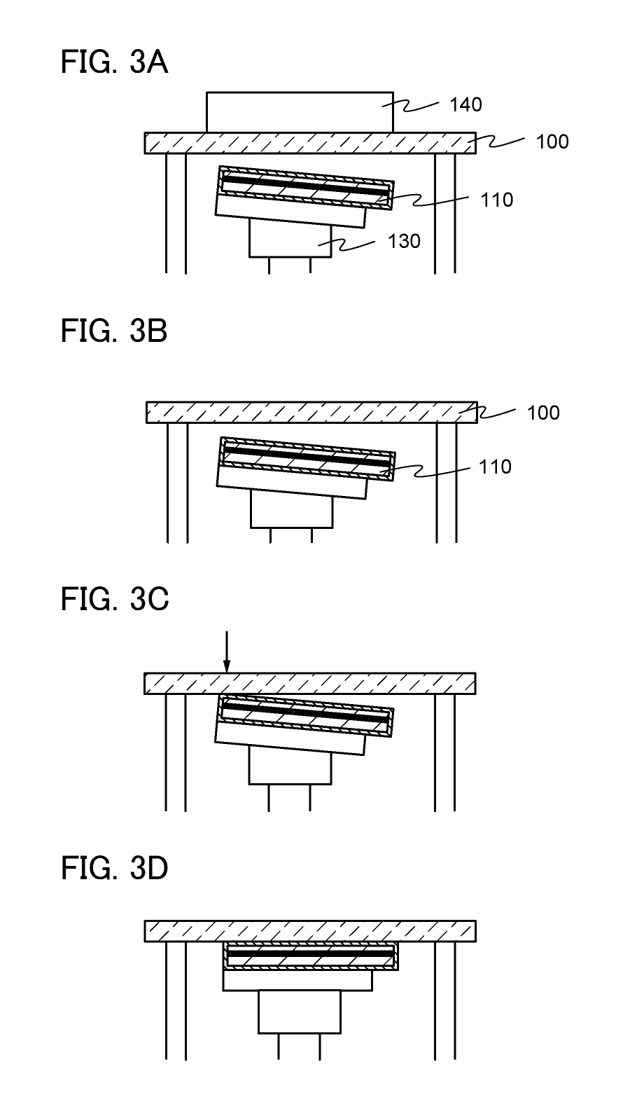

Furthermore, after the heated base substrate 100 is cooled to a desired temperature, the base substrate 100 may be in contact with the semiconductor substrate 110. This method is described with reference to FIGS. 3A to 3D.

As in FIG. 2A, the base substrate 100 is provided over the semiconductor substrate 110 at a small interval, and the semiconductor substrate 110 is provided to be slightly inclined to the base substrate 100. At this time, the base substrate 100 and a surface of the semiconductor substrate 110 in which the embrittled region is formed are provided to face each other. Next, a hot plate 140 is provided over the base substrate 100 and the base substrate 100 is heated by heating the hot plate 140 (see FIG. 3A). The heating temperature of the base substrate 100 is higher than or equal to 50° C. and lower than the strain point of the base substrate 100. There is no particular limitation on the heating time, which is set as appropriate so that the base substrate 100 reaches a desired temperature. For example, the base substrate 100 can be heated for 180 seconds.

Note that the case where the base substrate 100 is heated is described in this embodiment; however, one embodiment of the present invention is not limited to this. The semiconductor substrate 110 may be heated, or both of the base substrate 100 and the semiconductor substrate 110 may be heated.

Further, the base substrate is heated in this embodiment with the use of the hot plate 140; however, one embodiment of the present invention is not limited to this. For example, the base substrate may be heated by irradiation with lamp light of a halogen lamp. Alternatively, in a drying step after the wet treatment, the base substrate may be heated by spraying a gas whose temperature is higher than or equal to a heating temperature of the base substrate (such a method is also referred to as an air knife). When the base substrate is heated by spraying a gas whose temperature is higher than or equal to a heating temperature of the base substrate, the substrate can be heated at the same time as the drying step after the wet treatment. Accordingly, this is preferable because the process can be simplified. The temperature of a gas to be sprayed is set as appropriate so that the temperature of the base substrate is higher than or equal to 50° C. and lower than the strain point of the base substrate 100.

Next, the heated base substrate 100 is cooled to a desired temperature (see FIG. 3B). The cooling temperature is lower than or equal to 100° C., preferably higher than or equal to room temperature and lower than or equal to 95° C. There is no particular limitation on the cooling method, which is set as appropriate so that the base substrate 100 reaches a desired temperature. In this embodiment, the base substrate 100 is cooled down at room temperature and is cooled to room temperature.

Next, the base substrate 100 cooled to a desired temperature is pressed, whereby an end portion of the base substrate 100 is in contact with an end portion of the semiconductor substrate 110 (see FIG. 3C). Alternatively, with the use of a pin or the like, a point of the base substrate 100 or the semiconductor substrate 110, for example, a central portion of the base substrate 100 is pressed, whereby the base substrate 100 may be in contact with the semiconductor substrate 110. The base substrate 100 and the semiconductor substrate 110 start to be bonded to each other from a portion where they are in contact with each other, and then bonding is spontaneously generated over the entire surface (see FIGS. 3C and 3D).

Even when at least one of the base substrate 100 and the semiconductor substrate 110 is heated and then cooled to a desired temperature, voids generated at the bonding interface (especially, at a distance of approximately 5 mm from an edge of the substrate) can be reduced.

Further, even when at least one of the base substrate 100 and the semiconductor substrate 110 is heated and then cooled to a desired temperature, bonding defects can be reduced.

Note that in the case where the heated base substrate 100 is cooled to a desired temperature and then is in contact with the semiconductor substrate 110, as for the cooling temperature of the base substrate 100, the moisture content on the base substrate 100 and the semiconductor substrate 110 becomes optimal at the time when the cooling and then bonding temperature of the base substrate 100 is lower than or equal to 100° C., preferably higher than or equal to room temperature and lower than or equal to 95° C. It was found by trial and error of the present inventors. From the experimental result, it was found that when the heating temperature is higher than or equal to 100° C., moisture attaching to the surface of the substrate is insufficient and the spontaneous bonding does not occur.

Next, after the semiconductor substrate 110 and the base substrate 100 are bonded to each other, the semiconductor substrate 110 and the base substrate 100 that are bonded are preferably subjected to first heat treatment so that the bonding is strengthened. The heat temperature at this time is a temperature that does not promote separation at the embrittled region 112. For example, the temperature is set to lower than 400° C., preferably lower than or equal to 300° C. There is no particular limitation on the length of the time for the heat treatment, which is set as appropriate depending on the relation between the treatment time and the bonding strength. The heat treatment can be performed using a heating furnace such as a diffusion furnace or a resistance heating furnace, a rapid thermal annealing (RTA) apparatus, or the like. Further, only the region for bonding can be locally heated by irradiation with microwaves or the like. Note that when there is no problem with the bonding strength, the heat treatment may be omitted. In this embodiment, the heat treatment is performed at 200° C. for two hours.

Next, by performing second heat treatment, the semiconductor substrate 110 is separated into a semiconductor layer 116 and a semiconductor substrate 120 along the embrittled region 112 (see FIG. 1D). Through the above steps, an SOI substrate 180 in which the semiconductor layer 116 is provided over the base substrate 100 with the insulating layer 114 interposed therebetween can be obtained.

When the second heat treatment is performed, the atom added in the ion doping is deposited to microvoids which are formed in the embrittled region 112 by elevation of the temperature, and the internal pressure of the microvoids is increased. By the increased pressure, the microvoids in the embrittled region 112 are changed in volume. Thus, the semiconductor substrate 110 is separated along the embrittled region 112. Since the insulating layer 114 and the base substrate 100 are bonded to each other, the semiconductor layer 116 which is separated from the semiconductor substrate 110 is formed over the base substrate 100 with the insulating layer 114 interposed therebetween. Further, the temperature in this heat treatment is set so as not to exceed the strain point of the base substrate 100. For instance, when a glass substrate is used as the base substrate 100, the temperature for the heat treatment is preferably set to greater than or equal to 400° C. and less than or equal to 750° C. However, the temperature of the heat treatment is not limited to the above range as long as the glass substrate can withstand heat. The heat treatment can be performed using a heating furnace such as a diffusion furnace or a resistance heating furnace, a rapid thermal annealing (RTA) apparatus, a microwave heating apparatus, or the like. In this embodiment, the heat treatment is performed at 600° C. for two hours.

Note that, the second heat treatment step and the heat treatment step for causing separation along the embrittled region 112 may be performed at the same time, without performing the above first heat treatment.

When surplus moisture remains at the bonding interface between the base substrate 100 and the semiconductor substrate 110, the surplus moisture is heated and is evaporated in the above heat treatment step. Accordingly, a void is formed in a portion where surplus moisture is present. Further, when the void bursts, a semiconductor layer 118 or an insulating layer 114 is lost. Therefore, part of the bonding defects becomes apparent in the heat treatment step. However, by heating at least one of the base substrate 100 and the semiconductor substrate 110 before the base substrate 100 and the semiconductor substrate 110 are bonded to each other, the moisture content of both the substrates can be controlled and residual surplus moisture at the bonding interface can be suppressed. Accordingly, formation of a void at the bonding interface or a burst of the void can be prevented, whereby bonding defects which caused by surplus moisture and become apparent in the heat treatment step can be reduced. Similarly, even when at least one of the base substrate 100 and the semiconductor substrate 110 is heated and then cooled, the above effect can be obtained.

Next, planarization treatment is preferably performed on the semiconductor layer 116 of the SOI substrate 180. Even when unevenness or a defect due to the separation step or the ion irradiation step is caused on the surface of the semiconductor layer 116, by performing planarization treatment on the semiconductor layer 116, the surface of the semiconductor layer 116 can be planarized.

The planarization treatment can be performed by chemical mechanical polishing (CMP), etching treatment, laser light irradiation, or the like. Here, by irradiation of the semiconductor layer 116 with laser light, the semiconductor layer 116 is recrystallized and its surface is planarized.

By irradiation with laser light through the top surface of the semiconductor layer 116, the top surface of the semiconductor layer 116 is melted. After being melted, the semiconductor layer 116 is cooled and solidified, so that a semiconductor layer 118 having the top surface whose flatness is improved can be obtained. With use of laser light, the base substrate 100 is not directly heated; thus, increase in the temperature of the base substrate 100 can be suppressed. Therefore, a low-heat-resistant substrate such as a glass substrate can be used as the base substrate 100.

Note that it is preferable that the semiconductor layer 116 be partially melted by laser light irradiation. This is because, if the semiconductor layer 116 is completely melted, it is microcrystallized due to random nucleation after being changed into a liquid phase, so that crystallinity of the semiconductor layer 116 is highly likely to decrease. On the other hand, by partial melting, crystal growth proceeds from a non-melted solid phase part. Accordingly, defects in the semiconductor layer 116 can be reduced. Note that “complete melting” herein means that the semiconductor layer 116 is melted into a liquid state down to the vicinity of its lower interface. On the other hand, in this case, the term “partial melting” means that the upper part of the semiconductor layer 116 is melted and is in a liquid phase while the lower part thereof is not melted and is still in a solid phase.

For the laser light irradiation, a pulsed laser is preferably used. This is because a pulsed laser light having high energy can be emitted instantaneously and facilitates formation of a melting state. The repetition rate is preferably about greater than or equal to 1 Hz and less than or equal to 10 MHz.

When surplus moisture remains at the bonding interface between the base substrate 100 and the semiconductor substrate 110, the surplus moisture is heated and is evaporated in the laser irradiation step. Accordingly, a void is formed in a portion where surplus moisture is present. Further, when the formed void bursts, a semiconductor layer 118 or an insulating layer 114 is lost. Therefore, bonding defects become apparent in the laser irradiation step. Further, when a void is formed at the bonding interface in the above heat treatment step or laser irradiation step, the energy distribution of the laser light is uneven. Therefore, a bump of the semiconductor layer 118 or a lack of the semiconductor layer 118 or the insulating layer 114 may occur. However, by heating at least one of the base substrate 100 and the semiconductor substrate 110 before the base substrate 100 and the semiconductor substrate 110 are bonded to each other, residual surplus moisture at the bonding interface can be suppressed. Accordingly, formation of a void at the bonding interface or a burst of the void can be prevented, whereby bonding defects which caused by surplus moisture and become apparent in the laser irradiation step can be reduced. Further, planarization treatment step with laser light can be favorably performed. Similarly, even when at least one of the base substrate 100 and the semiconductor substrate 110 is heated and then cooled, the above effect can be obtained.

After the above irradiation with laser light, a step of thinning the semiconductor layer 118 may be performed. In order to reduce the thickness of the semiconductor layer 118, etch back treatment is employed. As the etch back treatment, either a dry etching or a wet etching, or a combination of both can be used. For example, in the case where the semiconductor layer 118 is formed using a silicon material, the semiconductor layer 118 can be thinned by dry etching using SF₆ and O₂ as a process gas.

Note that planarization treatment may also be performed on the semiconductor substrate 120 which has been separated, in addition to the SOI substrate 180. By planarizing the surface of the semiconductor substrate 120 which has been separated, the semiconductor substrate 120 can be reused in a process for manufacturing the SOI substrate.

Through the above process, an SOI substrate 190 in which the semiconductor layer 118 is provided over the base substrate 100 with the insulating layer 114 interposed therebetween can be manufactured (see FIG. 1E).

Note that although the case where the thinning step is performed after the planarization step on the semiconductor layer 116 is described in this embodiment, one embodiment of the present invention is not limited to this example, and the thinning step may be performed before the planarization step or the thinning step may be performed before and after the planarization step.

Note that although laser light is used to realize the reduction in defects and the improvement of the planarity in this embodiment, one embodiment of the present invention is not limited thereto. Reduction in defects and improvement in planarity may be realized with use of another method such as heat treatment. Even when defects are reduced and the planarity is improved by the heat treatment, it is effective to reduce bonding defects caused by surplus moisture by performing the heat treatment on at least one of the base substrate 100 and the semiconductor substrate 110. Further, only thinning treatment such as etching treatment may be performed if treatment for reducing defects is unnecessary.

### <Second Mode>

Next, a manufacturing method according to Second Mode will be described with reference to FIGS. 4A-1 to 4E. Second Mode is different from First Mode in that an insulating layer 101 is formed over the base substrate 100. Therefore, this point is mainly described below.

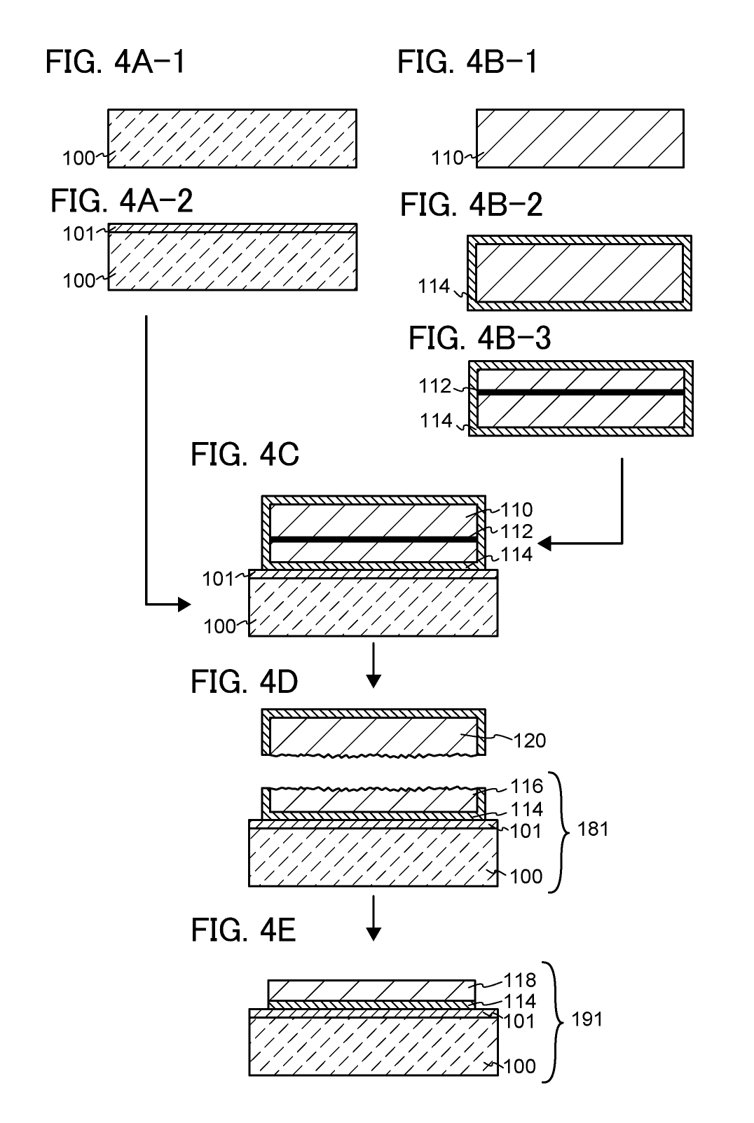

First, the base substrate 100 is prepared (see FIG. 4A-1), and the insulating layer 101 is formed over the base substrate (see FIG. 4A-2). FIG. 1A according to First Mode is referred to, for the base substrate 100.

There is no particular limitation on the method for forming the insulating layer 101, to which a sputtering method, a plasma CVD method, or the like can be applied, for example. Since the insulating layer 101 has a surface for the bonding, the insulating layer 101 is preferably formed such that this surface has high planarity. The insulating layer 101 can be formed using one or more materials selected from silicon oxide, silicon nitride, silicon oxynitride, silicon nitride oxide, aluminum oxide, aluminum nitride, aluminum oxynitride, aluminum nitride oxide, and the like. For example, when silicon oxide is used for the insulating layer 101, formation using an organosilane gas by a chemical vapor deposition method enables the insulating layer 101 to have excellent planarity. Note that although the insulating layer 101 has a single-layer structure in this embodiment, it may have a stack structure.

Next, a semiconductor substrate 110 is prepared as a bonding substrate, and an insulating layer 114 is formed on the surface of the semiconductor substrate 110. Then, the semiconductor substrate 110 is irradiated with ions, whereby an embrittled region 112 is formed (see FIGS. 4B-1 to 4B-3). The steps in FIGS. 4B-1 to 4B-3 are the same as those of FIGS. 1B-1 to 1B-3 according to First Mode; therefore the detailed description is not repeated.

Next, the base substrate 100 or the insulating layer 101 formed over the base substrate 100, and the semiconductor substrate 110 and the insulating layer 114 formed on the semiconductor substrate 110 are preferably subjected to surface treatment. The step is the same as that of First Mode; therefore the detailed description is not repeated.

Next, the base substrate 100 and the semiconductor substrate 110 are bonded to each other (see FIG. 4C). Specifically, the base substrate 100 faces the semiconductor substrate 110, and the insulating layer 101 formed over the base substrate 100 and the insulating layer 114 formed on the semiconductor substrate 110 are bonded to each other. At this time, it is preferable that at least one of the base substrate 100 and the semiconductor substrate 110 be heated to a desired temperature, and then the base substrate 100 and the semiconductor substrate 110 be bonded to each other. Alternatively, it is preferable that at least one of the base substrate 100 and the semiconductor substrate 110 be heated to a desired temperature and be cooled to a desired temperature, and then the base substrate 100 and the semiconductor substrate 110 be bonded to each other. For a method for bonding the base substrate 100 and the semiconductor substrate 110, FIGS. 2A and 2B and FIGS. 3A to 3D according to First Mode can be referred to.

Next, the semiconductor substrate 110 is separated into a semiconductor layer 116 and a semiconductor substrate 120 along the embrittled region 112 (see FIG. 4D). Through the above steps, an SOI substrate 181 in which the semiconductor layer 116 is provided over the base substrate 100 with the insulating layer 101 and the insulating layer 114 interposed therebetween can be obtained. Further, the planarization step or the like is performed on the semiconductor layer 116 of the SOI substrate 181, whereby an SOI substrate 191 in which the semiconductor layer 118 is provided over the base substrate 100 with the insulating layer 101 and the insulating layer 114 interposed therebetween can be obtained (see FIG. 4E). Note that for the steps in FIGS. 4D and 4E, the description of FIGS. 1D and 1E according to First Mode can be referred to.

By heating at least one of the base substrate 100 and the semiconductor substrate 110 when the base substrate 100 and the semiconductor substrate 110 are bonded to each other, rapid progress of the bonding can be suppressed. Thus, confinement of a gas or particles at the bonding interface can be suppressed, whereby voids generated at the bonding interface can be reduced. Further, by heating at least one of the base substrate 100 and the semiconductor substrate 110 when the base substrate 100 and the semiconductor substrate 110 are bonded to each other, residual surplus moisture at the bonding interface can be suppressed. Accordingly, bonding defects such as a bump and a lack of the semiconductor layer 118, which are caused by surplus moisture and become apparent in the heat treatment step, the planarization step, or the like, can be reduced. Similarly, even when at least one of the base substrate 100 and the semiconductor substrate 110 is heated and then cooled, the above effect can be obtained.

According to one embodiment of the disclosed invention, an SOI substrate in which bonding defects are sufficiently reduced can be manufactured. Further, characteristics of a semiconductor device using such an SOI substrate can be improved.

### Embodiment 2

In this embodiment, an SOI substrate which is different from that in Embodiment 1 and a manufacturing method thereof will be described.

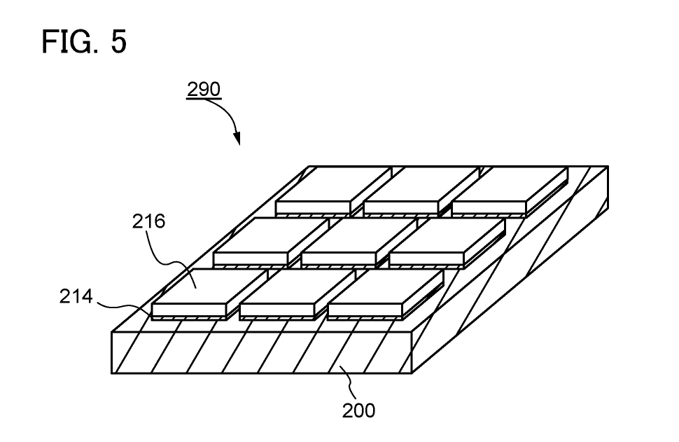

FIG. 5 is a perspective view illustrating a structural example of an SOI substrate 290. In the SOI substrate 290, a plurality of semiconductor layers 216 are provided over a base substrate 200. Each of the semiconductor layers 216 is provided over the base substrate 200 with an insulating layer 214 interposed therebetween.

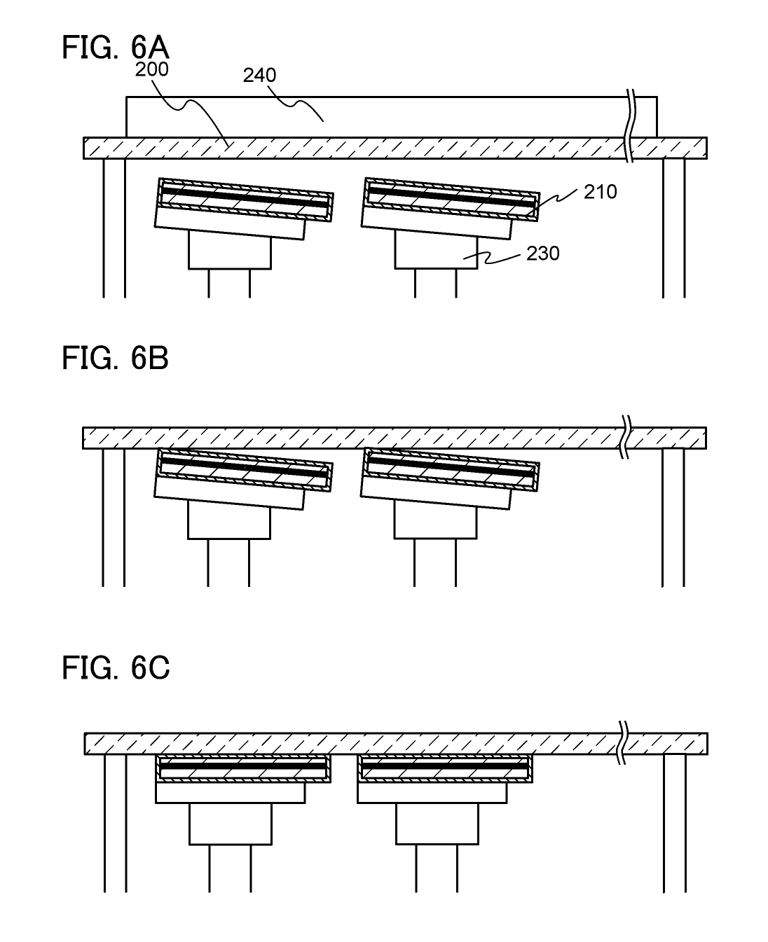

A manufacturing method according to Embodiment 2 will be described with reference to FIG. 5 and FIGS. 6A to 6C. Embodiment 2 is different from Embodiment 1 in that the plurality of semiconductor layers 216 are provided over the base substrate 200. Therefore, this point is mainly described below.

First, the base substrate 200 is prepared. As the base substrate 200, a mother glass substrate which has been developed for manufacturing liquid crystal panels is preferably used. As such a mother glass substrate, substrates having the following sizes are known: the third generation (550 mm×650 mm), the 3.5-th generation (600 mm×720 mm), the fourth generation (680 mm×880 mm, or 730 mm×920 mm), the fifth generation (1100 mm×1300 mm), the sixth generation (1500 mm×1850 mm), the seventh generation (1870 mm×2200 mm), the eighth generation (2200 mm×2400 mm), the ninth generation (2400 mm×2800 mm or 2450 mm×3050 mm), and the tenth generation (2950 mm×3400 mm), and the like. By manufacturing an SOI substrate 290 using a mother glass substrate with a large area for the base substrate 200, increase in the area of the SOI substrate can be realized.

By use of a mother glass substrate with a large area for the base substrate 200, increase in the area the area of the SOI substrate 290 can be realized. Increase in the area of the SOI substrate 290 allows many panels such as liquid crystal panels or many chips such as ICs, LSIs, or the like to be manufactured from one substrate 290, and thus the number of panels or chips manufactured from one substrate is increased; therefore, productivity can be significantly increased.

Note that an insulating layer may be formed over the above base substrate 200. The insulating layer formed over the base substrate 200 can be formed in the same manner as the insulating layer 101 illustrated in FIG. 4A-2 of Embodiment 1, and therefore details thereof are omitted.

Next, a plurality of semiconductor substrates 210 are prepared as bond substrates. In this embodiment, the semiconductor substrate 210 is processed into a desired size and shape. When the fact that the shape of the base substrate 200 to which the semiconductor substrates 210 are bonded is rectangular and a light-exposing region of a light exposure apparatus such as a reduced-projection light exposure apparatus is rectangular is taken into consideration, a shape of the semiconductor substrate 210 is preferably rectangular. For example, the semiconductor substrate 210 having a rectangular shape is processed so that the length of a long side thereof is n times (n is a given positive integer, n≧1 (n is 1 or more)) as long as that of one side of a region to be exposed to light of one shot from a reduced-projection light exposure apparatus.

The rectangular semiconductor substrate 210 can be formed by cutting a circular bulk semiconductor substrate. The semiconductor substrate 210 is cut by a cutting device such as a dicer or a wire saw, laser cutting, plasma cutting, electronic beam cutting, or any cutting means. Alternatively, before being sliced into the semiconductor substrate 210, an ingot for manufacturing semiconductor substrates can be processed into a rectangular solid so that it has a rectangular cross section, and this ingot that is a rectangular solid may be sliced to manufacture the rectangular semiconductor substrate 210.

Next, the insulating layer 214 is formed over each of the plurality of semiconductor substrates 210. After that, each of the plurality of semiconductor substrates 210 is irradiated with ions, whereby an embrittled region is formed in the semiconductor substrate 210. The steps are the same as those of FIGS. 1B-1 to 1B-3 according to Embodiment 1, and therefore details thereof are omitted.

Next, at least one of the base substrate 200 and the plurality of semiconductor substrates 210 is preferably subjected to surface treatment. The surface treatment step can be performed in a similar manner to Embodiment 1 and therefore details thereof are omitted.

Next, the base substrate 200 and the plurality of semiconductor substrates 210 are bonded to each other. Specifically, the base substrate 200 faces the semiconductor substrates 210, and the base substrate 200 and the insulating layer 214 formed on the semiconductor substrate 210 are bonded to each other. A method for bonding the base substrate 200 and the plurality of semiconductor substrates 210 will be described with reference to FIGS. 6A to 6C.

First, the base substrate 200 is provided over and close to the semiconductor substrate 210 mounted on a jig 230 at a small interval (about several millimeters). At this time, the base substrate 200 and a surface of the semiconductor substrate 210 in which the embrittled region is formed are provided to face each other. Further, with the use of the jig 230, the semiconductor substrate 210 is provided to be slightly inclined to the base substrate 200 (at about an angle of several degrees). The base substrate 200 is provided to be close and be inclined to the semiconductor substrate 210, whereby a first contact point which is a starting point of bonding of the base substrate 200 and the semiconductor substrate 210 can be set as appropriate, and the base substrate 200 and the semiconductor substrate 210 can be stably bonded to each other. Note that there is no particular limitation on the interval and the angle between the base substrate 200 and the semiconductor substrate 210, which are set as appropriate depending on the bonding.

Next, a hot plate 240 is provided over the base substrate 200 and the base substrate 200 is heated by heating the hot plate 240 (see FIG. 6A). The heating temperature of the base substrate 200 is higher than or equal to 50° C. and lower than or equal to 100° C., preferably, higher than or equal to 55° C. and lower than or equal to 95° C. There is no particular limitation on the heating time, which is set as appropriate so that the base substrate 200 reaches a desired temperature. For example, the base substrate 200 can be heated for 180 seconds.

Note that in the case where the base substrate 200 is heated to a desired temperature, as for the heating temperature of the base substrate 200, the moisture content on the base substrate 200 and the semiconductor substrate 210 becomes optimal at the time when the bonding temperature of the base substrate 200 is higher than or equal to 50° C. and lower than or equal to 100° C., preferably higher than or equal to 55° C. and lower than or equal to 95° C. It was found by trial and error of the present inventors. This is because, when the heating temperature is lower than 50° C., an effect of reducing bonding defects can not be sufficiently obtained because of excessive moisture attaching to the surface of the substrate and when the heating temperature is higher than or equal to 100° C., moisture attaching to the surface of the substrate is insufficient and the spontaneous bonding does not occur.

Note that the case where the base substrate 200 is heated is described in this embodiment; however, one embodiment of the present invention is not limited to this. The semiconductor substrate 210 may be heated, or both of the base substrate 200 and the semiconductor substrate 210 may be heated.

Further, the base substrate is heated in this embodiment with the use of the hot plate 240; however, one embodiment of the present invention is not limited to this. For example, the base substrate may be heated by irradiation with lamp light of a halogen lamp. Alternatively, in a drying step after the wet treatment, the base substrate may be heated by spraying a gas whose temperature is higher than or equal to a heating temperature of the base substrate. When the base substrate is heated by spraying a gas whose temperature is higher than or equal to a heating temperature of the base substrate, the substrate can be heated at the same time as the drying step after the wet treatment. Accordingly, this is preferable because the process can be simplified. The temperature of a gas to be sprayed is set as appropriate so that the temperature of the base substrate is higher than or equal to 50° C. and lower than or equal to 100° C., preferably, higher than or equal to 55° C. and lower than or equal to 95° C. Furthermore, the case where the entire surface of the base substrate 200 is heated is described in this embodiment; however, one embodiment of the present invention is not limited to this. A portion which is necessary for the bonding of the base substrate 200 may be heated.

Next, the base substrate 200 heated to a desired temperature is pressed, whereby an end portion of the base substrate 200 is in contact with an end portion of the semiconductor substrate 210 (see FIG. 6B). Alternatively, with the use of a pin or the like, a point of the base substrate 200 or the semiconductor substrate 210, for example, a central portion of the base substrate 200 is pressed, whereby the base substrate 200 may be in contact with the semiconductor substrate 210. The base substrate 200 and the semiconductor substrate 210 start to be bonded to each other from a portion where they are in contact with each other, and then bonding is spontaneously generated over the entire surface (see FIG. 6C).

Furthermore, after the heated base substrate 200 is cooled to a desired temperature, the base substrate 200 may be in contact with the semiconductor substrate 210. For this method, FIGS. 3A to 3D according to Embodiment 1 can be referred to. The heating temperature of the base substrate 200 is higher than or equal to 50° C. and lower than the strain point of the base substrate 200. The cooling temperature is lower than or equal to 100° C., preferably higher than or equal to room temperature and lower than or equal to 95° C. There is no particular limitation on the cooling method, which is set as appropriate so that the base substrate 200 reaches a desired temperature. In this embodiment, the base substrate is cooled down at room temperature and is cooled to room temperature.

Note that in the case where the heated base substrate 200 is cooled to a desired temperature and then is in contact with the semiconductor substrate 210, as for the cooling temperature of the base substrate 200, the moisture content on the base substrate 100 and the semiconductor substrate 210 becomes optimal at the time when the cooling and then bonding temperature of the base substrate 200 is lower than or equal to 100° C., preferably higher than or equal to room temperature and lower than or equal to 95° C. It was found by trial and error of the present inventors. From the experimental result, it was found that when the heating temperature is higher than or equal to 100° C., moisture attaching to the surface of the substrate is insufficient and the spontaneous bonding does not occur.

Two semiconductor substrates 210 are bonded to the base substrate 200 using two jigs in this embodiment; however, one embodiment of the present invention is not limited to this. A plurality of semiconductor substrates 210 may be sequentially bonded using one jig or a plurality of semiconductor substrates may be sequentially bonded using a plurality of jigs. When a plurality of semiconductor substrates 210 are bonded using three or more jigs, three or more semiconductor substrates 210 can be bonded at once.

Next, by performing heat treatment, the semiconductor substrate 210 is separated into a semiconductor layer 216 and a semiconductor substrate 210 along the embrittled region. Through the above steps, an SOI substrate 290 in which the plurality of semiconductor layers 216 are provided over the base substrate 200 can be obtained. The steps are the same as those of Embodiment 1, and therefore details thereof are omitted.

After that, treatment for reducing defects, planarization treatment, the thinning step, or the like can be performed on the plurality of semiconductor layers 216. The steps are the same as those of Embodiment 1, and therefore details thereof are omitted.

When one base substrate 200 and a plurality of semiconductor substrate 210 are bonded to each other, generation of voids in the outer edge portion of each of the plurality of semiconductor substrate 210 or generation of bonding defects caused by surplus moisture becomes a major problem. However, by heating at least one of the base substrate 200 and the semiconductor substrate 210 when the base substrate 200 and the semiconductor substrate 210 are bonded to each other, rapid progress of the bonding can be suppressed. Thus, confinement of a gas or particles at the bonding interface can be suppressed. Therefore, voids generated at the bonding interface can be reduced. Further, by heating at least one of the base substrate 200 and the semiconductor substrate 210 when the base substrate 200 and the semiconductor substrate 210 are bonded to each other, residual surplus moisture at the bonding interface can be suppressed. Accordingly, bonding defects such as a bump and a lack of the semiconductor layer 216, which are caused by surplus moisture in the heat treatment step, the planarization step, or the like, can be reduced. Thus, bonding defects are reduced, whereby productivity can be increased, when one base substrate 200 and the plurality of semiconductor substrate 210 are bonded to each other.

According to one embodiment of the disclosed invention, an SOI substrate in which bonding defects are sufficiently reduced can be manufactured. Further, characteristics of a semiconductor device using such an SOI substrate can be improved.

### Embodiment 3

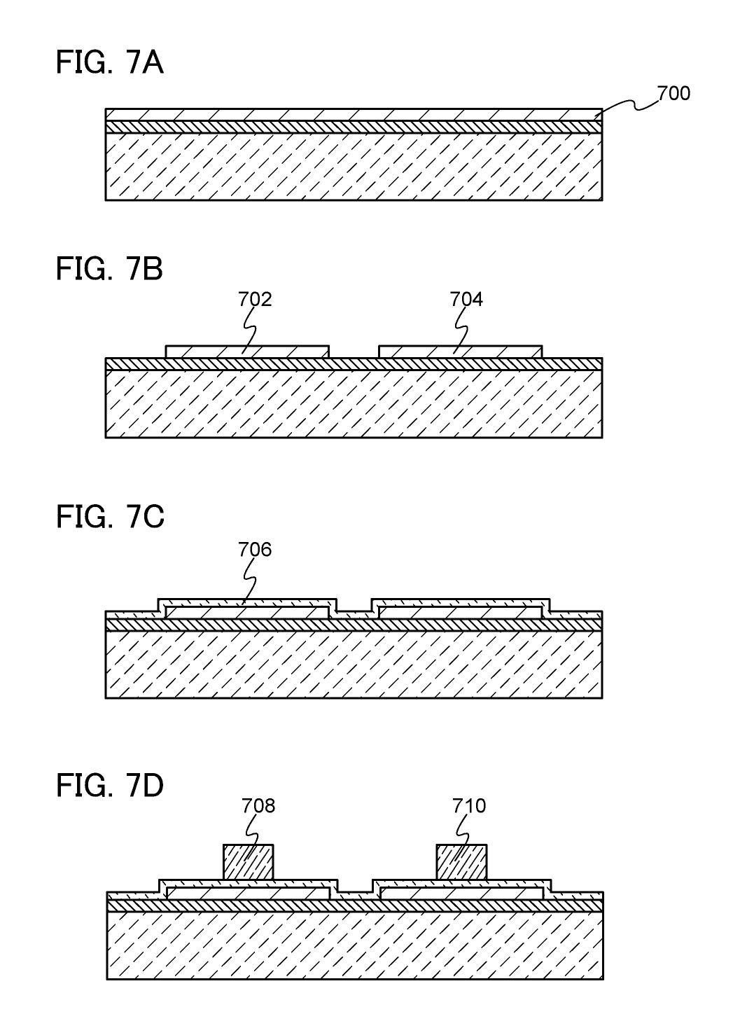

In this embodiment, details of the methods for manufacturing the semiconductor devices described in the above-described embodiments will be described with reference to FIGS. 7A to 7D, FIGS. 8A to 8D, and FIGS. 9A and 9B. Here, a method for manufacturing a semiconductor device including a plurality of transistors will be described as an example of the semiconductor device. Note that various kinds of semiconductor devices can be formed with the use of transistors described below in combination.

FIG. 7A is a cross-sectional view illustrating part of an SOI substrate which is manufactured by the method described in Embodiments 1 and 2 (for example, see FIG. 1E or the like).

In order to control threshold voltages of TFTs, a p-type impurity element such as boron, aluminum, or gallium or an n-type impurity element such as phosphorus or arsenic may be added to a semiconductor layer 700 (corresponding to the semiconductor layer 118 in FIG. 1E). A region to which the impurity element is added and the kind of the impurity element to be added can be changed as appropriate. For example, a p-type impurity element is added to a formation region of an n-channel TFT, and an n-type impurity element is added to a formation region of a p-channel TFT. The above impurity is preferably added at a dose of about greater than or equal to 1×10¹⁵ ions/cm² and less than or equal to 1×10¹⁷ ions/cm².

Then, the semiconductor layer 700 is divided into an island shape to form a semiconductor layer 702 and a semiconductor layer 704 (see FIG. 7B).

Next, a gate insulating film 706 is formed so as to cover the semiconductor layers 702 and 704 (see FIG. 7C). Here, a single-layer silicon oxide film is formed by a plasma CVD method. Alternatively, a film containing silicon oxynitride, silicon nitride oxide, silicon nitride, hafnium oxide, aluminum oxide, tantalum oxide, gallium oxide, or the like may be formed to have a single-layer structure or a stack structure as the gate insulating film 706.

As a manufacturing method other than a plasma CVD method, a sputtering method or a method using oxidation or nitridation by high-density plasma treatment can be given. High-density plasma treatment is performed using, for example, a mixed gas of a rare gas such as helium, argon, krypton, or xenon; and a gas such as oxygen, nitrogen oxide, ammonia, nitrogen, or hydrogen. In this case, by exciting plasma by introduction of microwaves, plasma with a low electron temperature and high density can be generated. The surfaces of the semiconductor layers are oxidized or nitrided by oxygen radicals (OH radicals may be included) or nitrogen radicals (NH radicals may be included) which are produced by such high-density plasma, whereby an insulating film is formed to a thickness greater than or equal to 1 nm and less than or equal to 20 nm, preferably greater than or equal to 2 nm and less than or equal to 10 nm so as to be in contact with the semiconductor layers.

Since the oxidation or nitridation of the semiconductor layers through the above high-density plasma treatment is a solid-phase reaction, the interface state density between the gate insulating film 706 and each of the semiconductor layers 702 and 704 can be drastically reduced. Further, the semiconductor layers are directly oxidized or nitrided by the high-density plasma treatment, whereby variation in the thickness of the insulating films to be formed can be suppressed. Since the semiconductor layers are single crystal films, even when the surfaces of the semiconductor layers are oxidized by a solid-phase reaction by using the high-density plasma treatment, a gate insulating film with high uniformity and low interface state density can be formed. When an insulating film formed by high-density plasma treatment as described above is used for a part or whole of the gate insulating film of a transistor, variation in characteristics can be suppressed.

Alternatively, the gate insulating film 706 may be formed by thermally oxidizing the semiconductor layer 702 and the semiconductor layer 704. In the case of such thermal oxidation, it is necessary to use a glass substrate having a certain degree of heat resistance.

Note that after a gate insulating film 706 containing hydrogen is formed, hydrogen contained in the gate insulating film 706 may be dispersed into the semiconductor layer 702 and the semiconductor layer 704 by performing heat treatment at a temperature of higher than or equal to 350° C. and lower than or equal to 450° C. In this case, the gate insulating film 706 can be formed using silicon nitride or silicon nitride oxide with a plasma CVD method. Further, a process temperature is preferably set to be equal to or lower than 350° C. If hydrogen is supplied to the semiconductor layer 702 and the semiconductor layer 704 in this manner, defects in the semiconductor layer 702, in the semiconductor layer 704, at the interface between the gate insulating film 706 and the semiconductor layer 702, and at the interface between the gate insulating film 706 and the semiconductor layer 704 can be effectively reduced.

Next, a conductive film is formed over the gate insulating film 706, and then, the conductive film is processed (patterned) into a predetermined shape, whereby an electrode 708 and an electrode 710 are formed over the semiconductor layer 702 and the semiconductor layer 704, respectively (see FIG. 7D). The conductive film can be formed by a CVD method, a sputtering method, or the like. The conductive film can be formed using a material such as tantalum (Ta), tungsten (W), titanium (Ti), molybdenum (Mo), aluminum (Al), copper (Cu), chromium (Cr), or niobium (Nb). Alternatively, an alloy material containing the above-described metal as a main component or a compound containing the above-described metal can also be used. Further alternatively, a semiconductor material, such as polycrystalline silicon which is obtained by doping a semiconductor with an impurity element that imparts a conductivity type, may be used.

Although the electrodes 708 and 710 are formed using a single-layer conductive film in this embodiment, the semiconductor device according to one embodiment of the disclosed invention is not limited to this structure. Each of the electrodes 708 and 710 may be formed with plural stacked conductive films. In the case of a two-layer structure, for example, a molybdenum film, a titanium film, a titanium nitride film, or the like may be used as a lower layer, and an aluminum film or the like may be used as an upper layer. In the case of a three-layer structure, a stack structure of a molybdenum film, an aluminum film, and a molybdenum film; a stack structure of a titanium film, an aluminum film, and a titanium film; or the like may be used.

Note that a mask used for forming the electrodes 708 and 710 may be formed using a material such as silicon oxide or silicon nitride oxide. In this case, a step of forming a mask by patterning a silicon oxide film, a silicon nitride oxide film, or the like is additionally needed. However, decrease in film thickness of the mask in etching is smaller than that in the case of using a resist material; thus, the electrodes 708 and 710 with more precise shapes can be formed. Alternatively, the electrodes 708 and 710 may be selectively formed employing a droplet discharge method without using a mask. Here, a droplet discharge method refers to a method in which droplets containing a predetermined composition are discharged or ejected to form a predetermined pattern, and includes an ink-jet method and the like in its category.

Alternatively, the electrodes 708 and 710 can be formed by etching the conductive film to have desired tapered shapes with an inductively coupled plasma (ICP) etching method with appropriate adjustment of etching conditions (e.g., the amount of electric power applied to a coiled electrode, the amount of electric power applied to a substrate-side electrode, the temperature of the substrate-side electrode, and the like). The tapered shape can be adjusted according to the shape of the mask. Note that as an etching gas, a chlorine-based gas such as chlorine, boron chloride, silicon chloride, or carbon tetrachloride, a fluorine-based gas such as carbon tetrafluoride, sulfur fluoride, or nitrogen fluoride, oxygen, or the like can be used as appropriate.

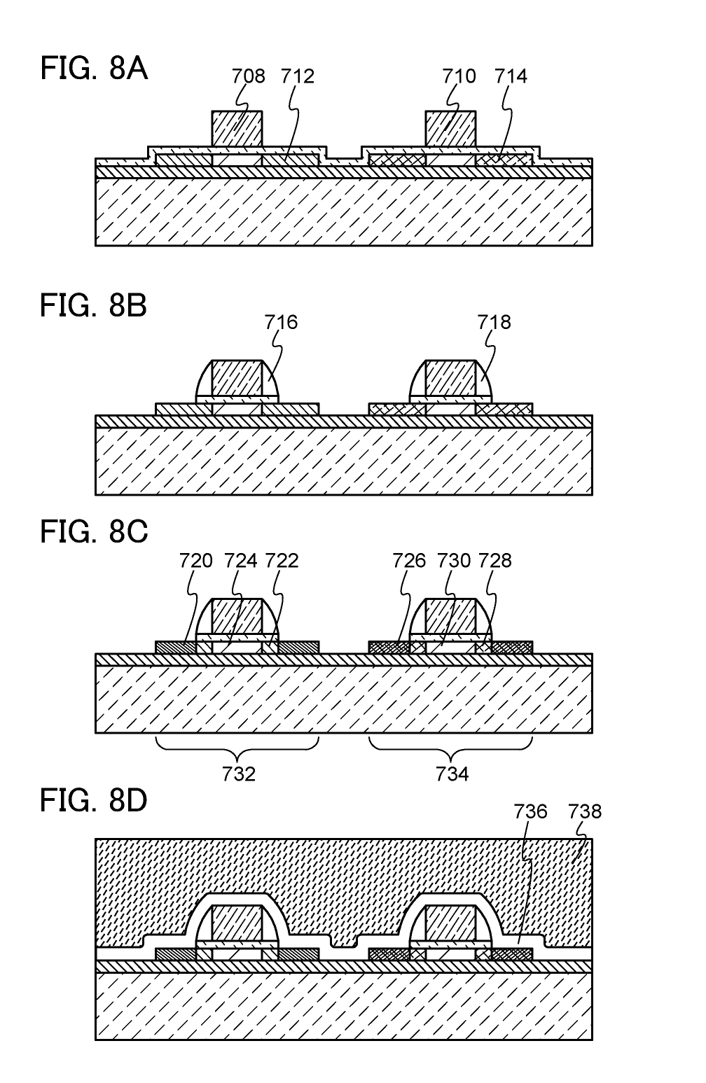

Next, an impurity element imparting one conductivity type is added to the semiconductor layer 702 and the semiconductor layer 704 by using the electrodes 708 and 710 as masks (see FIG. 8A). In this embodiment, an impurity element imparting n-type conductivity (for example, phosphorus or arsenic) is added to the semiconductor layer 702, and an impurity element imparting p-type conductivity (for example, boron) is added to the semiconductor layer 704. Note that when the impurity element imparting n-type conductivity is added to the semiconductor layer 702, the semiconductor layer 704 to which the impurity element imparting p-type conductivity is added is covered with a mask or the like so that the impurity element imparting n-type conductivity is added selectively. Further, when the impurity element imparting p-type conductivity is added to the semiconductor layer 704, the semiconductor layer 702 to which the impurity element imparting n-type conductivity is added is covered with a mask or the like so that the impurity element imparting p-type conductivity is added selectively. Alternatively, after one of the impurity element imparting p-type conductivity and the impurity element imparting n-type conductivity is added to the semiconductor layers 702 and 704, the other of the impurity element imparting p-type conductivity and the impurity element imparting n-type conductivity may be added to only one of the semiconductor layers at a higher concentration. By the addition of the impurity elements, impurity regions 712 and impurity regions 714 are formed in the semiconductor layer 702 and the semiconductor layer 704, respectively.

Next, a sidewall 716 is formed on the side surface of the electrode 708, and a sidewall 718 is formed on the side surface of the electrode 710 (see FIG. 8B). The sidewalls 716 and 718 can be formed by, for example, newly forming an insulating film so as to cover the gate insulating film 706 and the electrodes 708 and 710 and partly etching the newly formed insulating film with anisotropic etching. Note that the gate insulating film 706 may also be etched partially by the anisotropic etching described above. For the insulating film used for forming the sidewalls 716 and 718, a film containing silicon, silicon oxide, silicon nitride, silicon oxynitride, silicon nitride oxide, an organic material, or the like may be formed to have a single-layer structure or a stack structure with a plasma CVD method, a sputtering method, or the like. In this embodiment, a silicon oxide film with a thickness of 100 nm is formed by a plasma CVD method. In addition, as an etching gas, a mixed gas of CHF₃ and helium can be used. Note that the steps of forming the sidewalls 716 and 718 are not limited to the steps described here.

Next, impurity elements each imparting one conductivity type are added to the semiconductor layers 702 and 704 using the gate insulating film 706, the electrodes 708 and 710, and the sidewalls 716 and 718 as masks (see FIG. 8C). Note that the impurity element imparting the same conductivity type as the impurity element which has been added to the semiconductor layers 702 and 704 in the previous process is added to the semiconductor layers 702 and 704 at a higher concentration. Here, when the impurity element imparting n-type conductivity is added to the semiconductor layer 702, the semiconductor layer 704 to which the p-type impurity element is added is covered with a mask or the like so that the impurity element imparting n-type conductivity is added to the semiconductor layer 702 selectively. Further, when the impurity element imparting p-type conductivity is added to the semiconductor layer 704, the semiconductor layer 702 to which the impurity element imparting n-type conductivity is added is covered with a mask or the like so that the impurity element imparting p-type conductivity is added selectively.

By the addition of the impurity element, a pair of high-concentration impurity regions 720, a pair of low-concentration impurity regions 722, and a channel formation region 724 are formed in the semiconductor layer 702. In addition, by the addition of the impurity element, a pair of high-concentration impurity regions 726, a pair of low-concentration impurity regions 728, and a channel formation region 730 are formed in the semiconductor layer 704. The high-concentration impurity regions 720 and the high-concentration impurity regions 726 each function as a source or a drain, and the low-concentration impurity regions 722 and the low-concentration impurity regions 728 each function as a lightly doped drain (LDD) region.

Note that the sidewalls 716 formed over the semiconductor layer 702 and the sidewalls 718 formed over the semiconductor layer 704 may be formed so as to have the same length or different lengths in a direction in which carriers are transported (in a direction parallel to a so-called channel length). For example, each of the sidewalls 718 over the semiconductor layer 704 which constitutes part of a p-channel transistor is preferably formed to have a longer length in the direction in which carriers are transported than that of each of the sidewalls 716 over the semiconductor layer 702 which constitutes part of an n-channel transistor. By increasing the lengths of the sidewalls 718 of the p-channel transistor, a short channel effect due to diffusion of boron can be suppressed; therefore, boron can be added to the source and the drain at high concentration. Accordingly, the resistance of the source and the drain can be reduced.

In order to further reduce the resistance of the source and the drain, a silicide region may be formed by forming silicide in part of the semiconductor layers 702 and 704. The silicide is formed by placing a metal in contact with the semiconductor layers and causing a reaction between the metal and silicon in the semiconductor layers by heat treatment (e.g., a GRTA method, an LRTA method, or the like). For the silicide region, cobalt silicide or nickel silicide is preferably used. In the case where the semiconductor layers 702 and 704 are thin, silicide reaction may proceed to bottoms of the semiconductor layers 702 and 704. As a metal material used for the siliciding, the following can be used: titanium (Ti), nickel (Ni), tungsten (W), molybdenum (Mo), cobalt (Co), zirconium (Zr), hafnium (Hf), tantalum (Ta), vanadium (V), neodymium (Nd), chromium (Cr), platinum (Pt), palladium (Pd), or the like. Further, a silicide region can also be formed by irradiation with laser light or the like.

Through the above steps, an n-channel transistor 732 and a p-channel transistor 734 are formed. Note that although conductive films each serving as a source electrode or a drain electrode have not been formed at the stage in FIG. 8C, a structure including these conductive films each serving as a source electrode or a drain electrode may also be referred to as a transistor.

Next, an insulating film 736 is formed to cover the n-channel transistor 732 and the p-channel transistor 734 (see FIG. 8D). The insulating film 736 is not necessarily provided; however, the insulating film 736 can prevent impurities such as an alkali metal and an alkaline-earth metal from entering the n-channel transistor 732 and the p-channel transistor 734. Specifically, the insulating film 736 is preferably formed using a material such as silicon oxide, silicon nitride, silicon oxynitride, silicon nitride oxide, aluminum nitride, aluminum oxide, or the like. In this embodiment, a silicon nitride oxide film with a thickness of about 600 nm is used as the insulating film 736. In this case, the above-described hydrogenation step may be performed after the silicon nitride oxide film is formed. Note that although the insulating film 736 has a single-layer structure in this embodiment, the insulating film 736 may have a stack structure. For example, in the case of a two-layer structure, the insulating film 736 may have a stack structure of a silicon oxynitride film and a silicon nitride oxide film.

Next, an insulating film 738 is formed over the insulating film 736 so as to cover the n-channel transistor 732 and the p-channel transistor 734. The insulating film 738 is preferably formed using an organic material having heat resistance, such as polyimide, acrylic, benzocyclobutene, polyamide, or epoxy. Other than such an organic material, it is also possible to use a low-dielectric constant material (a low-k material), a siloxane-based resin, silicon oxide, silicon nitride, silicon oxynitride, silicon nitride oxide, phosphosilicate glass (PSG), borophosphosilicate glass (BPSG), alumina, or the like. Here, the siloxane-based resin corresponds to a resin including a Si—O—Si bond which is formed using a siloxane-based material as a starting material. The siloxane-based resin may include, besides hydrogen, at least one of fluorine, an alkyl group, or aromatic hydrocarbon as a substituent. Note that the insulating film 738 may be formed by stacking a plurality of insulating films formed from any of the above materials.

For the formation of the insulating film 738, the following method can be used depending on the material of the insulating film 738: a CVD method, a sputtering method, an SOG method, a spin coating method, a dip coating method, a spray coating method, a droplet discharge method (e.g., an ink jet method, screen printing, or offset printing), or a tool (equipment) such as a doctor knife, a roll coater, a curtain coater, or a knife coater.

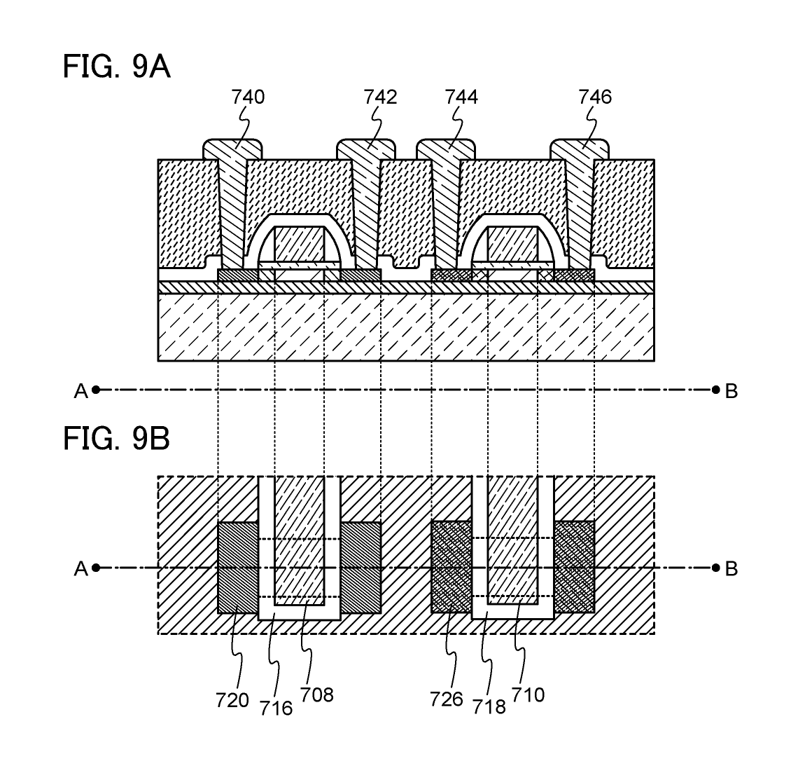

Next, contact holes are formed in the insulating films 736 and 738 so that each of the semiconductor layers 702 and 704 is partly exposed. Then, conductive films 740 and 742 are formed in contact with the semiconductor layer 702 through the contact holes, and conductive films 744 and 746 are formed in contact with the semiconductor layer 704 through the contact holes (see FIG. 9A). The conductive films 740, 742, 744, and 746 serve as source electrodes and drain electrodes of the transistors. Note that in this embodiment, as an etching gas for forming the contact holes, a mixed gas of CHF₃ and helium is employed; however, the etching gas is not limited thereto.

The conductive films 740, 742, 744, and 746 can be formed by a CVD method, a sputtering method, or the like. As a material of the conductive films, aluminum (Al), tungsten (W), titanium (Ti), tantalum (Ta), molybdenum (Mo), nickel (Ni), platinum (Pt), copper (Cu), gold (Au), silver (Ag), manganese (Mn), neodymium (Nd), carbon (C), silicon (Si), or the like can be used. Moreover, an alloy containing the above-described material as its main component or a compound containing the above-described material may be used. Further, each of the conductive films 740, 742, 744, and 746, either a single-layer structure or a stack structure may be used.

As an example of an alloy containing aluminum as its main component, an alloy containing aluminum as its main component and also containing nickel can be given. In addition, an alloy containing aluminum as its main component and also containing nickel and one or both of carbon and silicon can also be given as an example thereof. Aluminum and aluminum silicon (Al—Si), which have low resistance and are inexpensive, are suitable as a material for forming the conductive films 740, 742, 744, and 746. In particular, the aluminum silicon is preferable because a hillock can be prevented from generating due to resist baking at the time of patterning. Further, a material in which copper (Cu) is mixed into aluminum at approximately 0.5% may be used instead of silicon.

In the case where each of the conductive films 740, 742, 744, and 746 is formed to have a stack structure, a stack structure of a barrier film, an aluminum silicon film, and a barrier film; a stack structure of a barrier film, an aluminum silicon film, a titanium nitride film, and a barrier film; or the like may be used, for example. Note that the barrier film refers to a film formed using titanium, a nitride of titanium, molybdenum, a nitride of molybdenum, or the like. By forming the conductive films such that an aluminum silicon film is interposed between barrier films, generation of hillocks of aluminum or aluminum silicon can be further prevented. Moreover, by forming the barrier film using titanium that is a highly reducible element, even if a thin oxide film is formed on the semiconductor layers 702 and 704, the oxide film is reduced by the titanium contained in the barrier film, whereby favorable contact can be obtained between the semiconductor layer 702 and the conductive films 740 and 742 and between the semiconductor layer 704 and the conductive films 744 and 746. Further, it is also possible to stack a plurality of barrier films. In that case, for example, each of the conductive films 740, 742, 744, and 746 can be formed to have a five-layer structure of titanium, titanium nitride, aluminum silicon, titanium, and titanium nitride in order from the bottom or a stack structure of more than five layers.

As the conductive films 740, 742, 744, and 746, tungsten silicide formed by a chemical vapor deposition method using a tungsten hexafluoride gas and a silane gas may be used. Alternatively, tungsten formed by hydrogenation of tungsten hexafluoride may be used for the conductive films 740, 742, 744, and 746.

Note that the conductive films 740 and 742 are connected to the high-concentration impurity regions 720 of the n-channel transistor 732. The conductive films 744 and 746 are connected to the high-concentration impurity regions 726 of the p-channel transistor 734.

In a step in which the SOI substrate 190 reaches a high temperature, for example, in the formation step of the above silicide region or the formation step of the gate insulating film 706, when surplus moisture is present at the bonding interface, bonding defects such as protrusions or cracks of the semiconductor layer 118 or the semiconductor layer 216 may be generated. When the n-channel transistor 732 or the p-channel transistor 734 is formed in a portion where the semiconductor layer 118 or the semiconductor layer 216 protrudes, the characteristics and reliability are decreased as compared to the case where the surface of the semiconductor layer 118 or the semiconductor layer 216 is planarized. However, at least one of the base substrate 200 and the semiconductor substrate 210 is heated when the base substrate 200 and the semiconductor substrate 210 are bonded to each other, whereby residual surplus moisture at the bonding interface can be suppressed. Accordingly, in a step in which the SOI substrate 190 reaches a high temperature, bonding defects caused by surplus moisture such as bumps or lacks of the semiconductor layer 216 can be reduced. Thus, the characteristics and reliability of the n-channel transistor 732 or the p-channel transistor 734 can be improved.

FIG. 9B is a plan view of the n-channel transistor 732 and the p-channel transistor 734 which are illustrated in FIG. 9A. Here, a cross section taken along line A-B in FIG. 9B corresponds to FIG. 9A. For simplicity, the insulating films 736 and 738 and the conductive films 740, 742, 744, and 746 and the like are omitted in FIG. 9B.

Note that although the case where the n-channel transistor 732 and the p-channel transistor 734 each include one electrode serving as a gate electrode (the case where the n-channel transistor 732 and the p-channel transistor 734 include the electrodes 708 and 710) is described in this embodiment as an example, an embodiment of the disclosed invention is not limited to this structure. The transistors may have a multi-gate structure in which a plurality of electrodes serving as gate electrodes are included and electrically connected to one another.

In this embodiment, an SOI substrate in which bonding defects are sufficiently reduced is used, so that the yield of the semiconductor device can be improved. Note that the structure described in this embodiment can be used in appropriate combination with any of structures described in the other embodiments.

### Embodiment 4

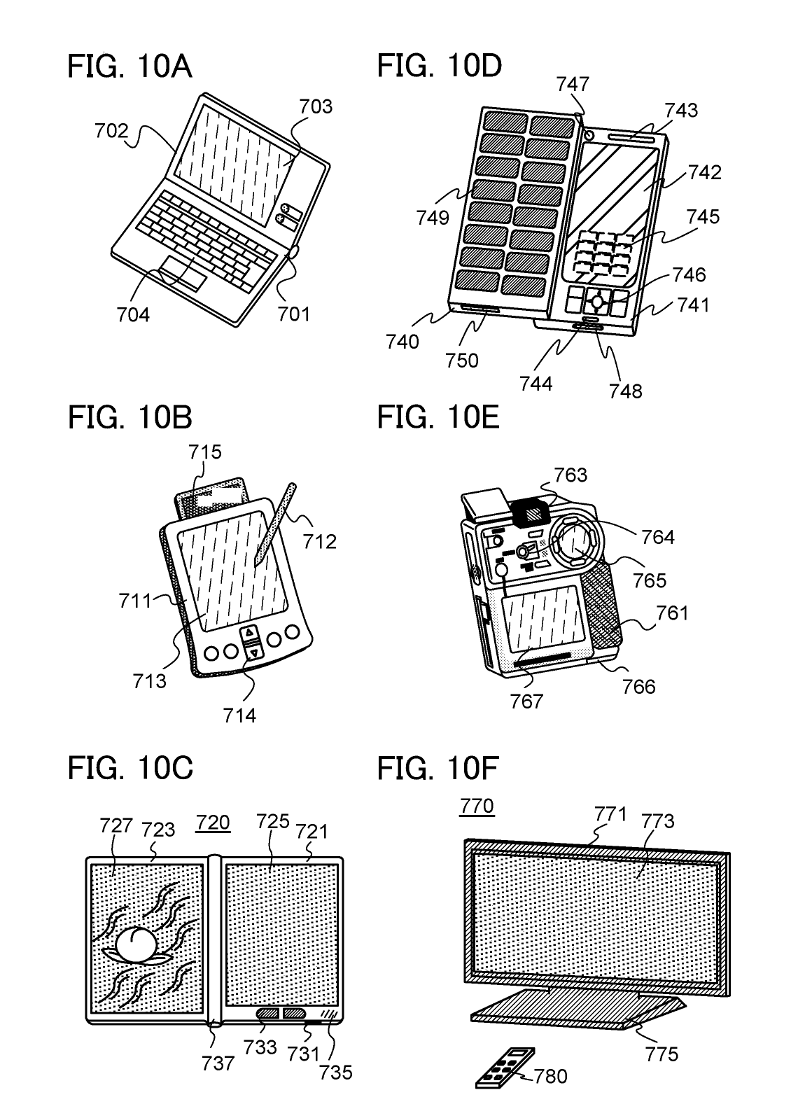

In this embodiment, application of the semiconductor device described in any of the above embodiments to an electronic device will be described with reference to FIGS. 10A to 10F. In this embodiment, applications of the semiconductor device to electronic devices such as a computer, a cellular phone handset (also referred to as a cellular phone or a cellular phone device), a personal digital assistant (including a portable game machine, an audio reproducing device, and the like), a digital camera, a digital video camera, electronic paper, and a television set (also referred to as a television or a television receiver) will be described.

FIG. 10A illustrates a laptop personal computer which includes a housing 601, a housing 602, a display portion 603, a keyboard 604, and the like. In the display portion 603, the semiconductor device described in Embodiment 3 is provided. Further, a driver circuit is provided inside at least one of the housings 601 and 602, and the driver circuit includes the semiconductor device described in Embodiment 3. Therefore, the laptop personal computer with high characteristics and high reliability can be realized.

FIG. 10B illustrates a personal digital assistant (PDA) which includes a main body 611 provided with a display portion 613, an external interface 615, operation buttons 614, and the like. In addition, a stylus 612 which controls the personal digital assistant and the like is provided. In the display portion 613, the semiconductor device described in Embodiment 3 is provided. Further, a driver circuit is provided inside the main body 611, and the driver circuit includes the semiconductor device described in Embodiment 3. Therefore, the personal digital assistant with high characteristics and high reliability can be realized.

FIG. 10C illustrates an e-book reader 620 including electronic paper. The e-book reader 620 includes two housings 621 and 623. The housing 621 and the housing 623 are respectively provided with a display portion 625 and a display portion 627. The housing 621 is combined with the housing 623 by a hinge 637, so that the e-book reader 620 can be opened and closed using the hinge 637 as an axis. The housing 621 is provided with a power button 631, operation keys 633, a speaker 635, and the like. In the display portion 627, the semiconductor device described in Embodiment 3 is provided. Further, a driver circuit is provided inside at least one of the housings 621 and 623, and the driver circuit includes the semiconductor device described in Embodiment 3. Therefore, the e-book reader with high characteristics and high reliability can be realized.

FIG. 10D illustrates a cellular phone handset, which includes two housings 640 and 641. Further, the housings 640 and 641 which are developed as illustrated in FIG. 10D can overlap with each other by sliding; thus, the size of the cellular phone can be decreased, which makes the cellular phone suitable for being carried. The housing 641 is provided with a display panel 642, a speaker 643, a microphone 644, operation keys 645, a pointing device 646, a camera lens 647, an external connection terminal 648, and the like. The housing 640 includes a solar cell 649 for charging the cellular phone handset, an external memory slot 650, and the like. In addition, an antenna is incorporated in the housing 641. In the display panel 642, the semiconductor device described in Embodiment 3 is provided. A driver circuit is provided inside at least one of the housings 640 and 641, and the driver circuit includes the semiconductor device described in Embodiment 3. Therefore, the cellular phone handset with high characteristics and high reliability can be realized.

FIG. 10E illustrates a digital camera, which includes a main body 661, a display portion 667, an eyepiece portion 663, an operation switch 664, a display portion 665, a battery 666, and the like. In the display portion 665, the semiconductor device described in Embodiment 3 is provided. Further, a driver circuit is provided inside the main body 661, and the driver circuit includes the semiconductor device described in Embodiment 3. Therefore, the digital camera with high characteristics and high reliability can be realized.

FIG. 10F illustrates a television set 670, which includes a housing 671, a display portion 673, a stand 675, and the like. The television set 670 can be operated with an operation switch of the housing 671 or a remote controller 680. In the display portion 673, the semiconductor device described in Embodiment 3 is provided. Further, a driver circuit is provided inside the housing 671 and the remote controller 680, and the driver circuit includes the semiconductor device described in Embodiment 3. Therefore, the television set with high characteristics and high reliability can be realized.

As described above, the electronic devices described in this embodiment each include the semiconductor device described in any of the above embodiments; thus, electronic devices with high characteristics and high reliability can be realized.

### Example 1

In this example, the measurement results of the number of bonding defects at the bonding interface between a semiconductor substrate and a base substrate (a central portion of an SOI substrate, here, a portion excluding a region which is 5 mm or less inward from the edge of the silicon layer) are described.

First, as the semiconductor substrate, a silicon substrate of 126.6 mm×126.66 mm was prepared. A silicon oxide film of 100 nm was formed over the silicon substrate by thermal oxidation treatment. Next, an embrittled region was formed by doping into the silicon substrate over which the silicon oxide film was formed with hydrogen ions through the silicon oxide film. The conditions of the hydrogen ion doping were set as follows: the acceleration voltage of 50 keV, the dose of 2.7×10¹⁶ ions/cm², and the beam current density of 6.35 μA/cm².

Next, as the base substrate, a glass substrate with a size of 320 mm×400 mm was prepared. After that, surface treatment was performed on the glass substrate and the silicon substrate. The surface treatment of the glass substrate was performed by scan irradiation using a Xe excimer UV lamp of a linear light source at 10 mm per second, as the dry treatment. After that, as the wet treatment, brush cleaning with an alkaline cleaner and two-fluid cleaning (a method in which pure water and air are sprayed together) were performed. Then, a gas was sprayed so that the glass substrate was dried. The surface treatment of the silicon substrate was performed by scan irradiation using a Xe excimer UV lamp of a linear light source at 10 mm per second, as the dry treatment. After that, as the wet treatment, megasonic cleaning with an alkaline cleaner was performed. Then, the silicon substrate was dried with IPA (a method in which water is replaced with isopropyl alcohol vapor).

Next, the glass substrate and the silicon substrate were disposed so that a surface of the glass substrate on which the surface treatment was performed and a surface of the silicon substrate with the embrittled region on which the surface treatment was performed faced each other, and the glass substrate was heated with the use of a hot plate. The four heating conditions were set as follows: heating to 60° C. (condition A: four silicon substrates), heating to 90° C. (condition B: four silicon substrates), heating to 60° C. and then cooling to room temperature (condition C: two silicon substrates), heating to 90° C. and then cooling to room temperature (condition D: one silicon substrate). In addition, a portion of the glass substrate to be bonded was heated for 180 seconds. Further, a condition that the glass substrate was not heated was set (condition E: four silicon substrates) for a comparative example.

Next, in condition A and condition B, the glass substrate heated to a desired temperature and the silicon substrate faced each other and the glass substrate was pressed, whereby an end portion of the glass substrate was in contact with an end portion of the silicon substrate. This contact caused spontaneous bonding between the glass substrate and the silicon substrate, and the glass substrate and the silicon substrate were bonded to each other. Further, in condition C and condition D, the glass substrate was heated to a desired temperature and then was cooled. After that, the glass substrate and the silicon substrate faced each other and the glass substrate was pressed, whereby an end portion of the glass substrate was in contact with an end portion of the silicon substrate. This contact caused spontaneous bonding between the glass substrate and the silicon substrate, and the glass substrate and the silicon substrate were bonded to each other. In condition E, the glass substrate and the silicon substrate faced each other and the glass substrate was pressed, while the glass substrate was kept at room temperature, whereby an end portion of the glass substrate was in contact with an end portion of the silicon substrate. This contact caused the spontaneous bonding between the glass substrate and the silicon substrate, and the glass substrate and the silicon substrate were bonded to each other.

Next, after all of the bonded glass substrates and silicon substrates were subjected to heat treatment so that the bonding was strengthened, each of the silicon substrates was separated along the embrittled region. Thus, an SOI substrate in which a silicon layer was provided over the glass substrate with the silicon oxide film interposed therebetween was obtained. The heat treatment was performed at 200° C. for two hours for strengthening the bonding, and then at 600° C. for two hours for the separation.

Next, the SOI substrate obtained as described above was irradiated with laser light. As a laser emitting laser light, a XeCl excimer laser (wavelength: 308 nm and repetition rate: 30 Hz) was used. The irradiation with laser light was performed with a nitrogen gas blown on the SOI substrate at room temperature in the following manner. The cross section of the laser light was shaped into a linear form by an optical system. The scanning rate of the laser light was set to 0.5 mm/sec and the number of beam shots was set to about 20.

Next, bonding defects of the SOI substrate obtained as described above were observed with a microscope. Specifically, at a central portion of an SOI substrate, here, a portion excluding a region which is 5 mm or less inward from the edge of the silicon layer with a size of 116.6 mm×116.6 mm, bonding defects such as bumps of the silicon layer or lacks of the silicon layer or the silicon oxide film were observed.

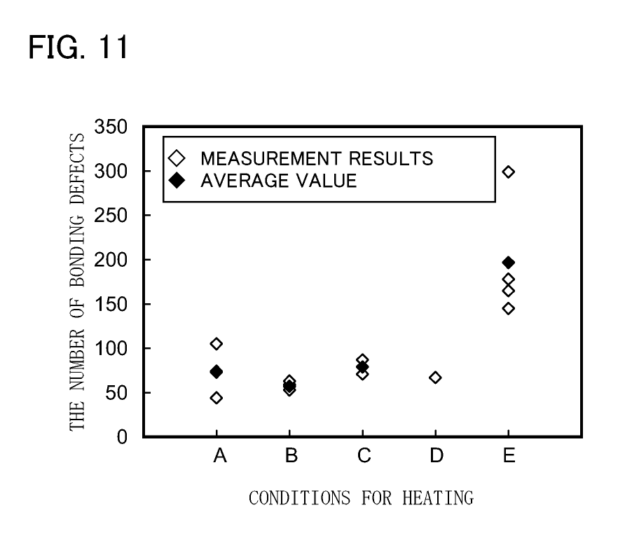

FIG. 11 shows the measurement results of the number of bonding defects. In FIG. 11, white rectangles represent the number of defects of each sample and black rectangles represent the average value of the number of defects under each of the conditions.

As shown in FIG. 11, in the case where the glass substrate was heated to 60° C. (condition A), and in the case where the glass substrate was heated to 90° C. (condition B), bonding defects could be reduced as compared to the case where the heating was not performed (condition E). Further, in the case where the glass substrate was heated to 60° C. and then cooled (condition C) and in the case where the glass substrate was heated to 90° C. and then cooled (condition D), bonding defects could be reduced as compared to the case where the heating was not performed (condition E).

The above results indicated that, the glass substrate was heated and then the glass substrate and the silicon substrate were bonded to each other (condition A and condition B), whereby bonding defects at the bonding interface between the glass substrate and the silicon substrate could be reduced. Further, the above results indicated that, the glass substrate was heated and cooled, and then the glass substrate and the silicon substrate were bonded to each other (condition C and condition D), whereby bonding defects at the bonding interface between the glass substrate and the silicon substrate could be reduced.

Bonding defects such as bumps of the silicon layer or lacks of the silicon layer or the silicon oxide film are caused by surplus moisture on the surface of the substrate, confinement of particles (dust) or a gas, or the like. Among them, surplus moisture at the bonding interface is one of major factors of bonding defects. The glass substrate is heated or the glass substrate is heated and cooled, whereby part of moisture attaching to the surface of the glass substrate is evaporated. Accordingly, surplus moisture can be reduced while moisture content necessary for bonding the surface of the glass substrate and the surface of the silicon substrate remains. Then, in the case where the glass substrate is heated (condition A and condition B) and in the case where the glass substrate is heated and then cooled (condition C and condition D), it is considered that bonding defects caused by surplus moisture were reduced.

### Example 2

In this example, the measurement results of the number of bonding defects at the bonding interface between a semiconductor substrate and a base substrate (an outer edge portion of an SOI substrate, here, a region which is 4 mm or less inward from the edge of the silicon layer) are described.

First, as the semiconductor substrate, a silicon substrate of 126.6 mm×126.66 mm was prepared. A silicon oxide film of 100 nm was formed over the silicon substrate by thermal oxidation treatment. Next, an embrittled region was formed by doping into the silicon substrate over which the silicon oxide film was formed with hydrogen ions through the silicon oxide film. The conditions of the hydrogen ion doping were set as follows: the acceleration voltage of 50 keV, the dose of 2.7×10¹⁶ ions/cm², and the beam current density of 6.35 μA/cm².

Next, as the base substrate, a glass substrate with a size of 320 mm×400 mm was prepared. After that, surface treatment was performed on the glass substrate and the silicon substrate. The surface treatment of the glass substrate was performed by scan irradiation using a Xe excimer UV lamp of a linear light source at 10 mm per second, as the dry treatment. After that, as the wet treatment, brush cleaning with an alkaline cleaner and two-fluid cleaning (a method in which pure water and air are sprayed together) were performed. Then, a gas was sprayed so that the glass substrate was dried. The surface treatment of the silicon substrate was performed by scan irradiation using a Xe excimer UV lamp of a linear light source at 10 mm per second, as the dry treatment. After that, as the wet treatment, megasonic cleaning with an alkaline cleaner was performed. Then, the silicon substrate was dried with IPA (a method in which water is replaced with isopropyl alcohol vapor).

Next, the glass substrate and the silicon substrate were disposed so that a surface of the glass substrate on which the surface treatment was performed and a surface of the silicon substrate on which the surface treatment was performed faced each other, and the glass substrate was heated with the use of a hot plate. The four heating conditions were set as follows: heating to 60° C. (condition A: four silicon substrates), heating to 90° C. (condition B: four silicon substrates), heating to 60° C. and then cooling to room temperature (condition C: two silicon substrates), heating to 90° C. and then cooling to room temperature (condition D: one silicon substrate). In addition, a portion of the glass substrate to be bonded was heated for 180 seconds. Further, a condition that the glass substrate was not heated was set (condition E: four silicon substrates) for a comparative example.

Next, the glass substrate and the silicon substrate were bonded to each other. In this example, in the bonding process, the time needed for the bonding was measured. Specifically, in the method where the glass substrate and the silicon substrate are provided to face each other and the glass substrate is pressed so that the glass substrate is in contact with the silicon substrate and the glass substrate and the silicon substrate are bonded to each other, the period from the start of the bonding of the glass substrate and the silicon substrate by the contact to the completion of the bonding after the spontaneous bonding progresses was measured with the use of a stop watch. The method for the bonding was the same as that of Example 1.

Next, after the bonded glass substrates and silicon substrates were subjected to heat treatment so that the bonding was strengthened, each of the silicon substrates was separated along the embrittled region. Thus, an SOI substrate in which a silicon layer was provided over the glass substrate with the silicon oxide film interposed therebetween was obtained. The heat treatment was performed at 200° C. for two hours for strengthening the bonding, and then at 600° C. for two hours for the separation.

Next, bonding defects of the SOI substrate obtained as described above were observed with a microscope. At this time, at the bonding interface of an outer edge portion of the SOI substrate (a region which is 4 mm or less inward from the edge of the silicon layer), bonding defects (voids) caused by confinement of a gas or particles were observed.

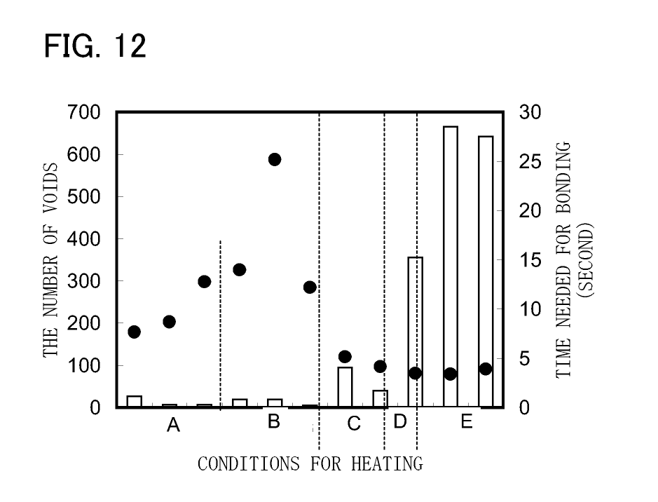

FIG. 12 shows the time needed for the bonding and the measurement results of the number of voids. In FIG. 12, black circles represent the time needed for the bonding of each sample and a bar graph represents the number of voids.

As shown in FIG. 12, under condition A in which the glass substrate was heated to 60° C., the time needed for the bonding was 7.67 seconds, 8.71 seconds, and 12.78 seconds and the number of voids was 27 pieces, 7, and 7, respectively. In contrast, under condition E in which the glass substrate was not heated, the time needed for the bonding was 3.49 seconds, 3.4 seconds, and 3.92 seconds and the number of voids was 356 pieces, 665, and 642, respectively.

The above results indicates that, in the case where the glass substrate is heated to 60° C. (condition A), the time needed for the bonding is increased as compare to the case where the glass substrate is not heated (condition E). Further, it was found that, in the case where the glass substrate is heated to 60° C., the number of voids is decreased as compare to the case where the glass substrate is not heated. Accordingly, it was found that, when the glass substrate is heated, rapid progress of the bonding is suppressed and generation of voids at an outer edge portion of the SOI substrate can be reduced.

Furthermore, it was found that, as shown in FIG. 12, in condition B in which the glass substrate is heated to 90° C. and conditions C and D in which the glass substrates are heated and then cooled, generation of voids at an outer edge portion of the SOI substrate can be reduced, as compared to condition E in which the glass substrate is not heated.

### Example 3

This example shows the measurement results of water (H₂O) and OH on the glass substrate, which are eliminated by heating the glass substrate.

First, as the base substrate, a glass substrate of with a size of 320 mm×400 mm was prepared. After that, surface treatment was performed on the glass substrate. The surface treatment was performed by irradiation using a Xe excimer UV lamp at 10 mm per second, as the dry treatment. After that, as the wet treatment, brush cleaning with an alkaline cleaner and two-fluid cleaning (method in which pure water and air are sprayed together) were performed. Then, a gas was sprayed so that the glass substrate was dried.

Next, the glass substrate was heated with the use of a hot plate. The two heating conditions were set as follows: heating to 60° C. and heating to 90° C. In addition, a portion of the glass substrate to be bonded was heated for 180 seconds. Further, a condition that the glass substrate was not heated was set for a comparative example. After that, the heated glass substrate and the glass substrate that was not heated were cut into pieces of 10 mm×10 mm, and water (H₂O) and OH on the glass substrate, which were eliminated, were measured using TDS (thermal desorption spectroscopy) analysis. Note that TDS analysis is an analysis method in which a sample is heated in a vacuum case and a gas component generated from the sample when the temperature of the sample is increased is detected by a quadrupole mass analyzer. Detected gas components are distinguished from each other by the value of m/z (mass/charge)

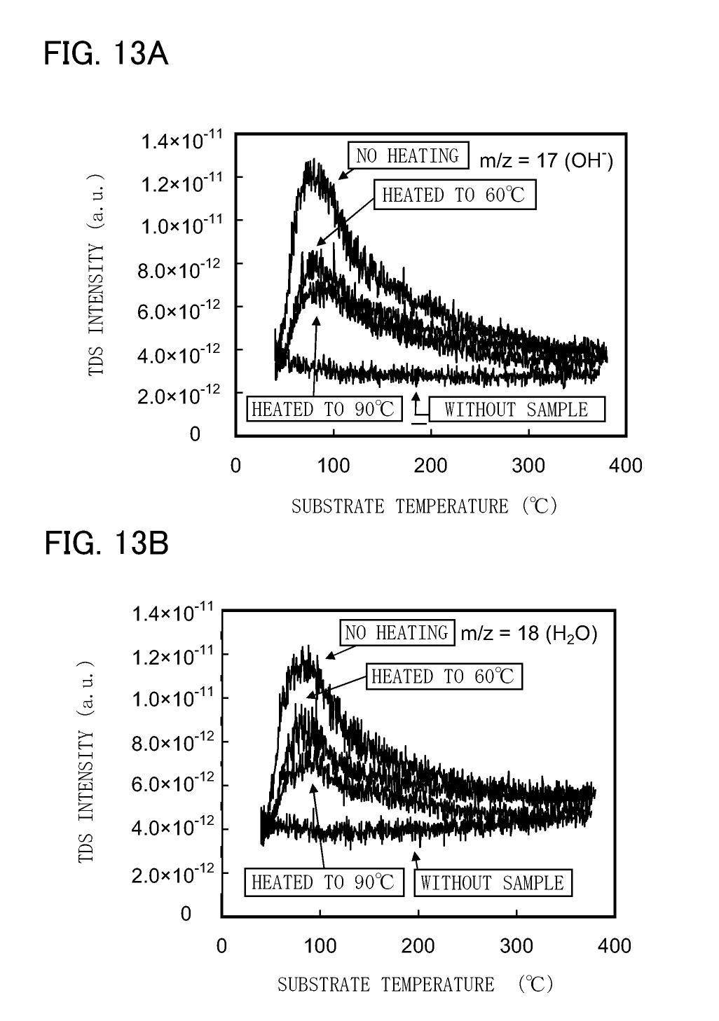

FIGS. 13A and 13B show the TDS analysis results. FIG. 13A shows TDS spectra when the value of m/z is 17 (OH) and FIG. 13B shows TDS spectra when the value of m/z is 18 (mainly H₂O). In FIGS. 13A and 13B, arrows are used to show the measurement results of the glass substrate heated to 60° C., the glass substrate heated to 90° C., and the glass substrate that was not heated and the measurement result without a sample.

As shown in FIGS. 13A and 13B, it is found that, in the case where the glass substrate is heated to 60° C. and in the case where the glass substrate is heated to 90° C., water (H₂O) and OH, which are eliminated, are decreased as compare to the case where the glass substrate that is not heated.

The above results indicate that, the glass substrate is heated, whereby moisture content attaching to the surface of the glass substrate is reduced. This attests the effect that, as described in Example 1, surplus moisture on the surface of the glass substrate is reduced by heating the glass substrate, whereby bonding defects are reduced. Further, this attests the effect that, as described in Example 2, by heating the glass substrate, generation of voids at an outer edge portion of the SOI substrate is reduced.

This application is based on Japanese Patent Application serial no. 2010-186594 filed with Japan Patent Office on Aug. 23, 2010, the entire contents of which are hereby incorporated by reference.

What is claimed is:

1. A method for manufacturing an SOI substrate comprising:
forming an insulating layer over a semiconductor substrate;
forming an embrittled region in the semiconductor substrate over which the insulating layer is formed by irradiating the semiconductor substrate with an ion;
heating a base substrate to reduce moisture content attaching to a surface of the base substrate, wherein the base substrate after the heating faces and is in contact with the semiconductor substrate in which the embrittled region is formed, so that the base substrate and the semiconductor substrate are bonded to each other; and
heating the bonded base substrate and semiconductor substrate to separate the semiconductor substrate along the embrittled region to form a semiconductor layer over the base substrate.

2. The method for manufacturing the SOI substrate, according to claim 1, wherein the semiconductor layer is formed over the base substrate, and then the base substrate over which the semiconductor layer is formed is irradiated with laser light.

3. The method for manufacturing the SOI substrate, according to claim 1, wherein the base substrate is heated to higher than or equal to 55° C. and lower than or equal to 95° C. when the base substrate is heated.

4. The method for manufacturing the SOI substrate, according to claim 1, wherein the base substrate is heated by spraying a gas whose temperature is higher than or equal to a heating temperature of the base substrate, when the base substrate is heated.

5. The method for manufacturing the SOI substrate, according to claim 2, wherein the base substrate is cooled to higher than or equal to room temperature and lower than or equal to 95° C. when the base substrate is heated and then cooled.

6. The method for manufacturing the SOI substrate, according to claim 1, wherein a glass substrate is used as the base substrate.

7. The method for manufacturing the SOI substrate, according to claim 1, wherein ozone or oxygen in an active state is combined with ultraviolet light to perform surface treatment on the base substrate and the semiconductor substrate before the base substrate and the semiconductor substrate are bonded to each other.

8. A method for manufacturing an SOI substrate comprising:
forming an insulating layer over a semiconductor substrate;
forming an embrittled region in the semiconductor substrate over which the insulating layer is formed by irradiating an ion to the semiconductor substrate;
heating and then cooling a base substrate to reduce moisture content attaching to a surface of the base substrate, and the cooled base substrate faces and is in contact with the semiconductor substrate in which the embrittled region is formed, so that the base substrate and the semiconductor substrate are bonded to each other; and
heating the bonded base substrate and semiconductor substrate to separate the semiconductor substrate along the embrittled region to form a semiconductor layer over the base substrate.

9. The method for manufacturing the SOI substrate, according to claim 8, wherein the semiconductor layer is formed over the base substrate, and then the base substrate over which the semiconductor layer is formed is irradiated with laser light.

10. The method for manufacturing the SOI substrate, according to claim 8, wherein the base substrate is heated to higher than or equal to 55° C. and lower than or equal to 95° C. when the base substrate is heated.

11. The method for manufacturing the SOI substrate, according to claim 8, wherein the base substrate is heated by spraying a gas whose temperature is higher than or equal to a heating temperature of the base substrate, when the base substrate is heated.

12. The method for manufacturing the SOI substrate, according to claim 8, wherein the base substrate is cooled to higher than or equal to room temperature and lower than or equal to 95° C. when the base substrate is heated and then cooled.

13. The method for manufacturing the SOI substrate, according to claim 8, wherein a glass substrate is used as the base substrate.

14. The method for manufacturing the SOI substrate, according to claim 8, wherein ozone or oxygen in an active state is combined with ultraviolet light to perform surface treatment on the base substrate and the semiconductor substrate before the base substrate and the semiconductor substrate are bonded to each other.

15. A method for manufacturing an SOI substrate comprising:
forming an insulating layer each on a plurality of semiconductor substrates;
forming an embrittled region each in the plurality of semiconductor substrates on which the insulating layers are formed by irradiating an ion to each of the semiconductor substrates;
heating a base substrate to reduce moisture content attaching to a surface of the base substrate, and the heated base substrate faces and is in contact with the plurality of semiconductor substrates in which the embrittled regions are formed, so that the base substrate and the plurality of semiconductor substrates are bonded to each other; and
heating the bonded base substrate and plurality of semiconductor substrates to separate the plurality of semiconductor substrates along the embrittled regions to form a plurality of semiconductor layers over the base substrate.

16. The method for manufacturing the SOI substrate, according to claim 15, wherein a semiconductor layer is formed over the base substrate, and then the base substrate over which the semiconductor layer is formed is irradiated with laser light.

17. The method for manufacturing the SOI substrate, according to claim 15, wherein the base substrate is heated to higher than or equal to 55° C. and lower than or equal to 95° C. when the base substrate is heated.

18. The method for manufacturing the SOI substrate, according to claim 15, wherein the base substrate is heated by spraying a gas whose temperature is higher than or equal to a heating temperature of the base substrate, when the base substrate is heated.

19. The method for manufacturing the SOI substrate, according to claim 16, wherein the base substrate is cooled to higher than or equal to room temperature and lower than or equal to 95° C. when the base substrate is heated and then cooled.

20. The method for manufacturing the SOI substrate, according to claim 15, wherein a glass substrate is used as the base substrate.

21. The method for manufacturing the SOI substrate, according to claim 15, wherein ozone or oxygen in an active state is combined with ultraviolet light to perform surface treatment on the base substrate and the semiconductor substrate before the base substrate and the semiconductor substrate are bonded to each other.
